(19) United States
(12) Patent Application Publication
(10) Pub. No.: US 2016/0079219 A1
(43) Pub. Date: Mar. 17, 2016

(54) SEMICONDUCTOR DEVICE

(71) Applicant: Kabushiki Kaisha Toshiba, Tokyo (JP)

(72) Inventor: Eiichi Hosomi, Kawasaki Kanagawa (JP)

(21) Appl. No.: 14/645,333

(22) Filed: Mar. 11, 2015

(30) Foreign Application Priority Data
Sep. 11, 2014 (JP) 2014-185364

(51) Int. Cl. H01L 25/18; H01L 23/31; H01L 23/498

(52) U.S. Cl. CPC H01L 25/18; H01L 23/49827; H01L 23/49838; H01L 23/49833; H01L 23/3142

(57) ABSTRACT

According to one embodiment, there is provided a semiconductor device including an interposer, a logic chip, a memory chip, and a package substrate. In the interposer, first via is configured to electrically connect a signal terminal of the logic chip and a signal terminal of the memory chip to each other through a substrate. Multi-layer wiring is disposed on first principal surface side of the substrate. Power supply terminal of the logic chip is electrically connected to the multi-layer wiring. Power supply pad is disposed on the first principal surface side of the substrate and configured to be electrically connected to the power supply terminal of the logic chip through the multi-layer wiring. A metal wire is connected to power supply pad. The package substrate includes a power supply wiring. The power supply pad and the power supply wiring are electrically connected to each other through the metal wire.

### CROSS-REFERENCE TO RELATED APPLICATIONS

This application is based upon and claims the benefit of priority from Japanese Patent Application No. 2014-185364, filed on Sep. 11, 2014; the entire contents of which are incorporated herein by reference.

### FIELD

Embodiments described herein relate generally to a semiconductor device.

### BACKGROUND

In semiconductor devices, in order to improve the packaging density, logic chips and memory chips are stacked on a package substrate. At that time, in order to operate the logic chips appropriately, it is desirable to supply source voltages of appropriate levels to power supply terminals of the logic chips.

### BRIEF DESCRIPTION OF THE DRAWINGS

FIG. 1 is a cross-sectional view that illustrates the configuration of a semiconductor device according to a first embodiment;

FIG. 2 is an enlarged cross-sectional view that illustrates the configuration of multi-layer wirings according to the first embodiment;

FIG. 3 is a plan view that illustrates the configuration of wirings according to the first embodiment;

FIG. 4 is a plan view that illustrates the configuration of wirings according to the first embodiment;

FIGS. 5A to 5G are cross-sectional views that illustrate a method of manufacturing a semiconductor device according to the first embodiment;

FIGS. 6A to 6D are cross-sectional views that illustrate the method of manufacturing the semiconductor device according to the first embodiment;

FIGS. 7A to 7C are cross-sectional views that illustrate a method of manufacturing a semiconductor device according to a modified example of the first embodiment;

FIG. 8 is a cross-sectional view that illustrates the configuration of a semiconductor device according to a second embodiment;

FIG. 9 is a cross-sectional view that illustrates the configuration of a semiconductor device according to a third embodiment;

FIG. 10 is an enlarged cross-sectional view that illustrates multi-layer wirings according to the third embodiment;

FIGS. 11A to 11D are cross-sectional views that illustrate a method of manufacturing a semiconductor device according to the third embodiment;

FIGS. 12A to 12C are cross-sectional views that illustrate the method of manufacturing the semiconductor device according to the third embodiment;

FIGS. 13A to 13C are cross-sectional views that illustrate a method of manufacturing a semiconductor device according to a modified example of the third embodiment;

FIG. 14 is a cross-sectional view that illustrates the configuration of a semiconductor device according to a fourth embodiment;

FIG. 15 is a cross-sectional view that illustrates the configuration of a semiconductor device according to a fifth embodiment;

FIGS. 16A to 16C are cross-sectional views that illustrate the method of manufacturing the semiconductor device according to the fifth embodiment;

FIG. 17 is a cross-sectional view that illustrates the configuration of a semiconductor device according to a sixth embodiment;

FIG. 18 is an enlarged cross-sectional view that illustrates multi-layer wirings according to the sixth embodiment;

FIGS. 19A to 19E are cross-sectional views that illustrate a method of manufacturing a semiconductor device according to the sixth embodiment; and

FIGS. 20A to 20C are cross-sectional views that illustrate the method of manufacturing the semiconductor device according to the sixth embodiment.

### DETAILED DESCRIPTION

In general, according to one embodiment, there is provided a semiconductor device including an interposer, a logic chip, a memory chip, and a package substrate. The logic chip is mounted on a first principal surface of the interposer. The memory chip is mounted on a second principal surface of the interposer, the second principal surface is a principal surface arranged on an opposite side of the first principal surface. On the package substrate, the logic chip, the interposer, and the memory chip are mounted. The interposer including a substrate, a first via, a multi-layer wiring, and a power supply pad. The first via is configured to electrically connect a signal terminal of the logic chip and a signal terminal of the memory chip to each other through the substrate. The multi-layer wiring is disposed on the first principal surface side of the substrate. The power supply terminal of the logic chip is electrically connected to the multi-layer wiring. The power supply pad is disposed on the first principal surface side of the substrate and configured to be electrically connected to the power supply terminal of the logic chip through the multi-layer wiring. A metal wire is connected to the power supply pad. The package substrate includes a power supply wiring. The power supply pad and the power supply wiring are electrically connected to each other through the metal wire.

Exemplary embodiments of a semiconductor device will be explained below in detail with reference to the accompanying drawings. The present invention is not limited to the following embodiments.

### First Embodiment

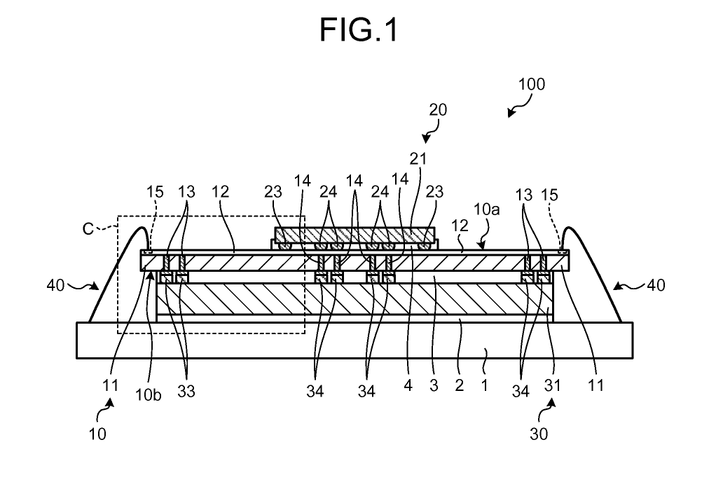

A semiconductor device 100 according to a first embodiment will be described with reference to FIG. 1. FIG. 1 is a schematic cross-sectional view that illustrates the configuration of the semiconductor device 100.

In the semiconductor device 100, in order to improve the packaging density, a chip on chip (CoC) technology for stacking a logic chip 20 and a memory chip 30 on a package substrate 1 is used.

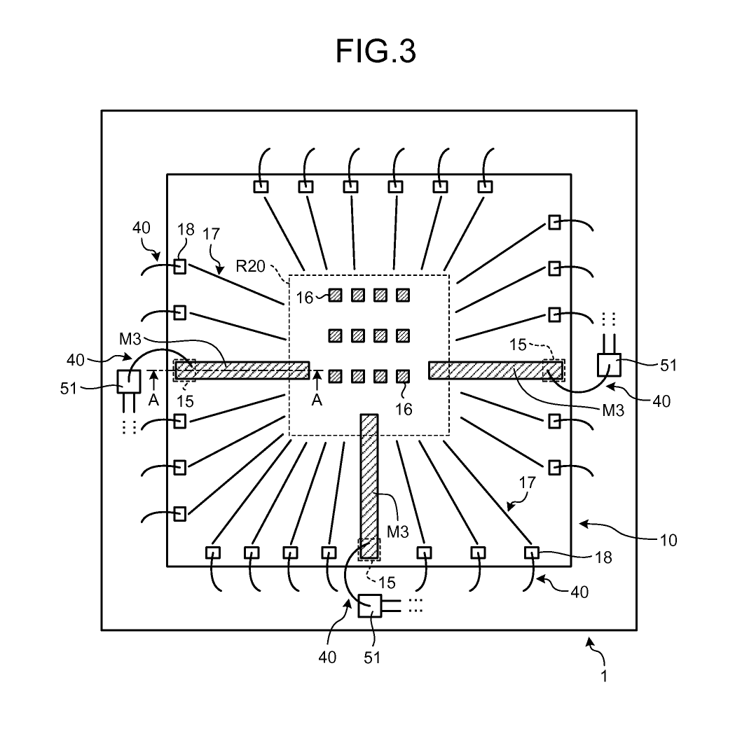

At this time, since implementation of a large capacity is required for the memory chip 30, the plane dimension of the memory chip 30 tends to be larger than that of the logic chip 20. For example, a case will be considered in which a redistribution layer is formed on the memory chip 30, the redistribution layer is covered with an insulating layer (for example, a layer of polyimide), and the logic chip 20 is arranged on the insulating layer in the semiconductor device 100. In such a case, even when power is to be supplied to the logic chip 20 using a wiring of the redistribution layer, it is necessary to draw a plurality of wirings for signals between the logic chip 20 and the memory chip 30 in addition to a wiring of a power supply, and accordingly, it is difficult to configure the wiring width for the power supply to be large (see FIG. 3). Accordingly, a voltage drop due to a wiring at the time of transmitting power may be easily increased, and electric potential of the power supply supplied to the logic chip 20 may easily decrease, whereby there is a possibility that the logic chip 20 does not normally operate.

Thus, in the first embodiment, a multi-layer wiring 12 is disposed in an interposer 10 that is inserted between the logic chip 20 and the memory chip 30, and a power supply terminal 23 of the logic chip 20 and a metal wire 40 are connected through the multi-layer wiring 12, whereby a voltage drop at the time of transmitting power can be suppressed.

More specifically, the semiconductor device 100 includes: a package substrate 1; a memory chip 30; an interposer 10; a logic chip 20; and a plurality of metal wires 40. The interposer 10 has a first principal surface 10a and a second principal surface 10b. The second principal surface 10b is a principal surface of the interposer 10 that is disposed on a side opposite to the first principal surface 10a.

On the package substrate 1, the memory chip 30, the interposer 10, and the logic chip 20 are stacked. The plane dimension of the package substrate 1, for example, is larger than that of any one of the memory chip 30, the interposer 10, and the logic chip 20. In a perspective view in a direction perpendicular to the first principal surface 10a, the package substrate 1 includes the memory chip 30, the interposer 10, and the logic chip 20. The package substrate 1 includes a predetermined wiring (for example, a power supply wiring 51 illustrated in FIG. 3) and may include a conductor post (not illustrated in the figure) passing through it. In such a case, it may be unconfigured such that one end of the conductor post is connected to the metal wire 40 through a predetermined wiring, and the other end of the conductor post is connected to a conductor ball (not illustrated in the figure). The conductor ball may serve as an external connection terminal (for example, a power supply terminal). As the package substrate 1, for example, a printed wiring board that is formed using an epoxy-based resin or the like and has a wiring being printed on the surface thereof may be used.

The memory chip 30 is mounted on the package substrate 1. For example, the memory chip 30 is mounted to the package substrate 1 by a mount resin 2. As the mount resin 2, for example, a conductive paste, an insulating paste, an insulating film, or the like may be used. In addition, the memory chip 30 is mounted on the second principal surface 10b of the interposer 10. For example, a gap between the memory chip 30 and the interposer 10 is sealed using a underfill resin 3 (for example, an epoxy-based resin). The plane dimension of the memory chip 30 is smaller than that of each of the package substrate 1 and the interposer 10 and is larger than that of the logic chip 20. In a perspective view in a direction perpendicular to the first principal surface 10a, the memory chip 30 is included in the package substrate 1 and the interposer 10 and includes the logic chip 20.

For example, the memory chip 30 includes a chip main body 31, a power supply terminal 33, and a signal terminal 34. As each of the power supply terminal 33 and the signal terminal 34, a conductor bump formed using solder or the like is used. The chip main body 31 includes a semiconductor substrate and has a multi-layer wiring structure. The multi-layer wiring structure is arranged on the surface of the semiconductor substrate. A part of an uppermost wiring layer of the multi-layer wiring structure is disposed as a pad, and each of the power supply terminal 33 and the signal terminal 34 is electrically connected to the pad. In addition, in an outer peripheral portion of the memory chip 30, a signal terminal not illustrated in the figure may be arranged. As the signal terminal, a conductor bump formed using solder or the like is used.

The interposer 10 is inserted between the logic chip 20 and the memory chip 30. On the first principal surface 10a of the interposer 10, the logic chip 20 is mounted, and, on the second principal surface 10b of the interposer 10, the memory chip 30 is mounted. The plane dimension of the interposer 10 is smaller than that of the package substrate 1 and is larger than that of each of the logic chip 20 and the memory chip 30. The interposer 10 will be described later in detail. In a perspective view in a direction perpendicular to the first principal surface 10a, the interposer 10 is included in the package substrate 1 and includes the logic chip 20 and the memory chip 30.

The logic chip 20 is mounted on the package substrate 1 through the interposer 10 and the memory chip 30. In addition, the logic chip 20 is mounted on the first principal surface 10a of the interposer 10. For example, a gap between the logic chip 20 and the interposer 10 is sealed using a sealing resin 4 (for example, an epoxy-based resin). The plane dimension of the logic chip 20 is smaller than that of any one of the package substrate 1, the memory chip 30, and the interposer 10. In a perspective view in a direction perpendicular to the first principal surface 10a, the logic chip 20 is included in the package substrate 1, the memory chip 30, and the interposer 10.

For example, the logic chip 20 includes a chip main body 21, a power supply terminal 23, and a signal terminal 24. As each of the power supply terminal 23 and the signal terminal 24, a conductor bump formed using solder or the like is used. The chip main body 21 includes a semiconductor substrate and has a multi-layer wiring structure. The multi-layer wiring structure is arranged on the rear surface of the semiconductor substrate. A part of the lowermost wiring layer of the multi-layer wiring structure is disposed as a pad, and each of the power supply terminal 23 and the signal terminal 24 is electrically connected to the pad.

Each of the plurality of metal wires 40 connects a predetermined pad among a plurality of pads (see FIG. 3) disposed on the first principal surface 10a of the interposer 10 and a predetermined wiring disposed on the package substrate 1 to each other. For example, the metal wire 40 connects a power supply pad 15, which is disposed on the first principal surface 10a of the interposer 10, to be described later and a power supply wiring 51 disposed on the package substrate 1 to each other (see FIG. 3). Each of the plurality of metal wires 40, for example, may be formed using a material having gold or copper as its main composition.

Next, the configuration of the interposer 10 will be described in detail. The interposer 10 is configured to relay a signal transfer between the logic chip 20 and the memory chip 30 and relay power transmission from the power supply wiring 51 (see FIG. 3) of the package substrate 1 to the logic chip 20. In addition, the interposer 10 achieves a role of signal transmission between the logic chip 20 and the package substrate 1.

More specifically, the interposer 10 includes: a substrate 11; a via (first via) 14; a multi-layer wiring 12; a via 13; and a power supply pad 15.

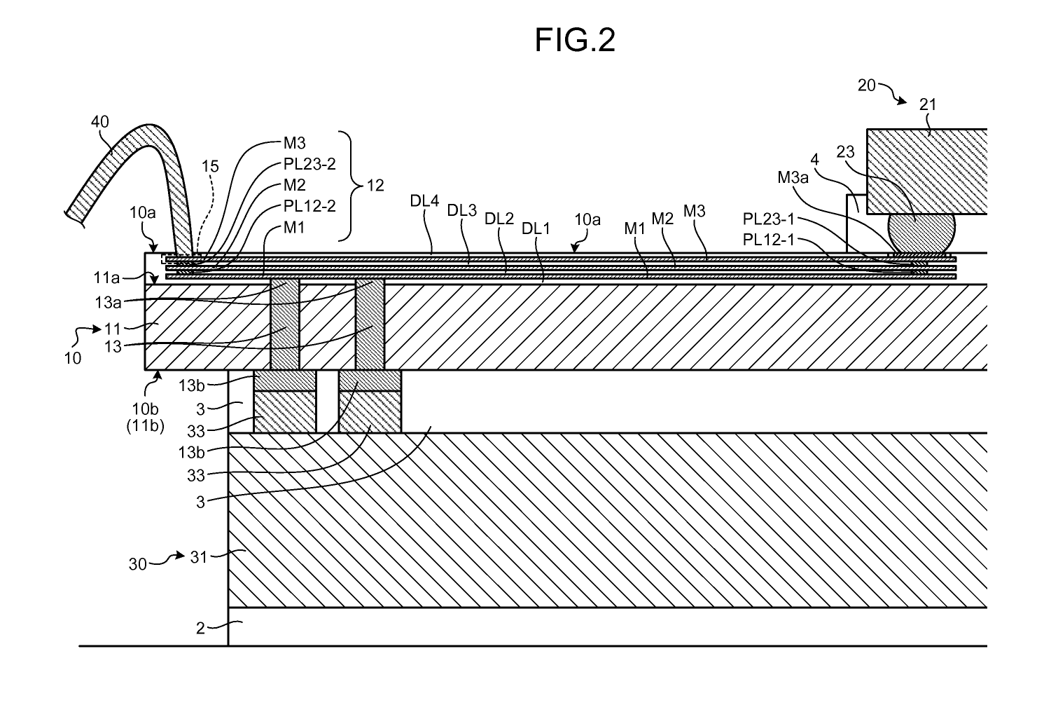

The substrate 11 is formed using semiconductor (for example, silicon, glass, or organic material). As illustrated in FIG. 2, a rear surface 11b of the substrate 11 forms the second principal surface 10b of the interposer 10. On the surface 11a of the substrate 11, a multi-layer wiring structure including the multi-layer wiring 12 is arranged. The surface of the multi-layer wiring structure forms the first principal surface 10a of the interposer 10. FIG. 2 is an enlarged cross-sectional view that illustrates the configuration of the multi-layer wiring 12 and is an enlarged cross-sectional view of a portion C illustrated in FIG. 1.

The via 14 illustrated in FIG. 1 passes through the substrate 11 from the surface 11a to the rear surface 11b (see FIG. 2). An end portion of the via 14 that is disposed on the first principal surface 10a side is connected to the signal terminal 24 of the logic chip 20 through the wiring disposed inside the multi-layer wiring structure and a plug (not illustrated in the figure). An end portion of the via 14 that is disposed on the second principal surface 10b side is connected to the signal terminal 34 of the memory chip 30. Accordingly, the via 14 electrically connects the signal terminal 24 of the logic chip 20 and the signal terminal 34 of the memory chip 30 to each other.

The multi-layer wiring 12 illustrated in FIG. 2 is disposed on the first principal surface 10a side of the substrate 11. The multi-layer wiring 12 electrically connects the power supply terminal 23 of the logic chip 20 and the power supply pad 15 to each other. For example, the multi-layer wiring 12 includes wirings M1 to M3 of a plurality of layers and a plurality of plugs PL12-1, PL23-1, PL12-2, and PL23-2. The wiring M3 of the uppermost layer among the wirings M1 to M3 of the plurality of layers is connected to the power supply terminal 23 of the logic chip 20 through a junction layer M3a on the logic chip 20 side and is connected to the power supply pad 15 on the metal wire 40 side. Each of the wirings M1 to M3 of the plurality of layers, for example, may be formed using a material having aluminum or copper as its main composition. Each of the plurality of plugs PL12-1, PL23-1, PL12-2, and PL23-2, for example, may be formed using a material having tungsten or copper as its main composition. The junction layer M3a, for example, is formed by using a material having copper at its main composition.

The wirings M2 and M1 of layers lower than the uppermost layer of the wirings M1 to M3 of the plurality of layers are connected to the wiring M3 of the uppermost layer in parallel therewith in the sectional view. In other words, the wiring M2 is connected to the wiring M3 of the uppermost layer through the plug PL23-1 on the logic chip 20 side. In addition, the wiring M2 is connected to the wiring M3 of the uppermost layer through the plug PL23-2 on the metal wire 40 side. The wiring M1 is connected to the wiring M3 of the uppermost layer through the plug PL12-1, the wiring M2, and the plug PL23-1 on the logic chip 20 side. In addition, the wiring M1 is connected to the wiring M3 of the uppermost layer through the plug PL12-2, the wiring M2, and the plug PL23-2 on the metal wire 40 side.

It should be noted that, on the surface 11a of the substrate 11, a multi-layer wiring structure in which the insulating layers DL1 to DL4 and the wirings M1 to M3 are alternately stacked a plurality of times is formed.

The via 13 illustrated in FIG. 2 passes through the substrate 11 from the surface 11a to the rear surface 11b. An end portion 13a of the via 13 that is disposed on the first principal surface 10a side is connected to the wiring M1 of the lowermost layer of the multi-layer wiring 12. An end portion 13b of the via 13 that is disposed on the second principal surface 10b side is connected to the power supply terminal 33 of the memory chip 30. Accordingly, the via 13 electrically connects the power supply terminal 33 of the memory chip 30 and the multi-layer wiring 12 to each other.

The power supply pad 15 is disposed on the first principal surface 10a side of the substrate 11. The power supply pad 15 is positioned on the peripheral side of the first principal surface 10a. The power supply pad 15 is electrically connected to the power supply terminal 23 of the logic chip 20 through the multi-layer wiring 12 and is electrically connected to the power supply terminal 33 of the memory chip 30 through the multi-layer wiring 12 and the via 13.

The metal wire 40 is connected to the power supply pad 15. In other words, a part of a conductive layer including the wiring M3 of the uppermost layer is disposed as the power supply pad 15, and a portion of the uppermost insulating layer DL4 that corresponds to the power supply pad 15 is open, and the surface of the power supply pad 15 is exposed. The metal wire 40 is connected to the exposed surface of the power supply pad 15 through an alloyed junction or the like. For example, the power supply pad 15 is connected to the power supply wiring 51 disposed on the package substrate 1 through the metal wire 40.

As illustrated in FIG. 2, the multi-layer wiring 12 that transmits power makes a parallel connection between the power supply terminal 23 of the logic chip 20 and the metal wire 40 in a stacking direction in the cross-sectional view. Accordingly, the combined resistance of a transmission path from the metal wire 40 to the power supply terminal 23 of the logic chip 20 can be configured to be low in an easy manner, and thus, a voltage drop at the time of transmitting power can be suppressed.

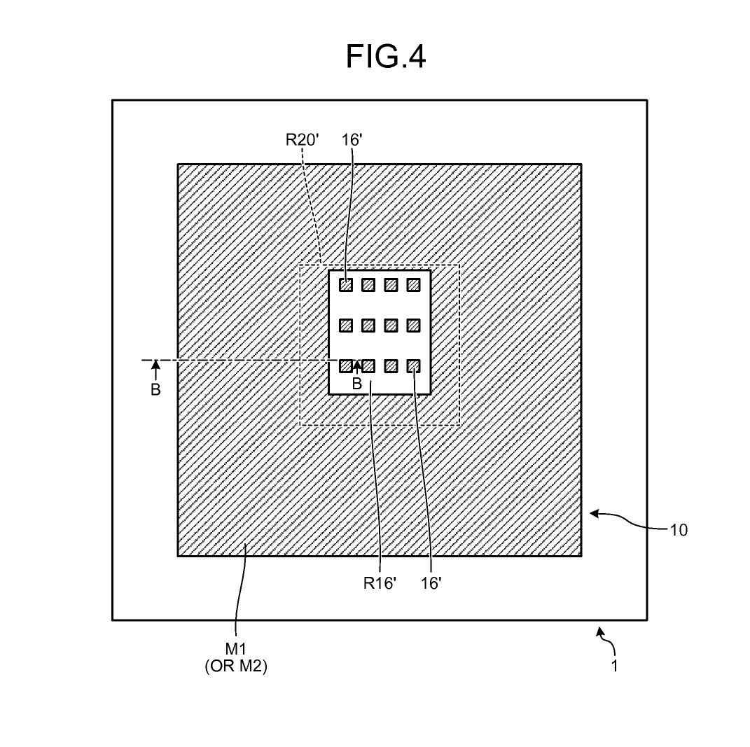

Next, the layout configuration of wirings of each layer in the multi-layer wiring 12 will be described with reference to FIGS. 3 and 4. FIG. 3 is a plan view that illustrates the layout configuration of the wiring M3 of the uppermost layer of the multi-layer wiring 12. In FIG. 3, a portion corresponding to the enlarged cross-sectional view illustrated in FIG. 2 is denoted by line A-A. FIG. 4 is a plan view that illustrates the layout configuration of the wirings M1 and M2 of the layers lower than the uppermost layer in the multi-layer wiring 12. In FIG. 4, a portion corresponding to the enlarged cross-sectional view illustrated in FIG. 2 is denoted by line B - B.

In the uppermost wiring layer, as illustrated in FIG. 3, in addition to the wiring M3 used for power supply, wirings for various signals are arranged. For example, in a region R20 corresponding to the logic chip 20, wirings 16 used for connecting the signal terminals 24 of the logic chip 20 and the vias 14 of the interposer 10 are arranged. The region R20 corresponding to the logic chip 20 may be configured as an area overlapping the logic chip 20 in the case of being projected in a direction perpendicular to the first principal surface 10a. On the outer side of the region R20 corresponding to the logic chip 20, a plurality of linear wirings 17 are arranged. For this reason, areas in which the wirings M3 used for power supply can be arranged are restricted, and the wiring M3 for power supply, for example, has an approximately rectangular shape extending from the center side to the peripheral side. In the plan view, the power supply pad 15 is connected to an end portion of the wiring M3 used for power supply that is disposed on the peripheral side. The power supply pad 15 is connected to the power supply wiring 51 of the package substrate 1 through the metal wire 40.

It should be noted that, in the plan view, the pad 18 used for a signal is connected to a portion of each of the wirings 17 used for various signals that is disposed near the end portion of the interposer 10, and the pad 18 used for a signal is electrically connected to a wiring (not illustrated in the figure) used for a signal in the package substrate 1 through the metal wire 40.

On a wiring layer disposed below the uppermost layer, as illustrated in FIG. 4, wirings M1 (or M2) used for power supply are arranged, and wirings of various signals are hardly arranged. For example, in a region R20′ corresponding to the logic chip 20, wirings 16′ used for connecting the signal terminals 24 of the logic chip 20 and the vias 14 of the interposer 10 are arranged. On the outer side of the region R20′ corresponding to the logic chip 20, wirings of signals are not arranged. For this reason, a large region for arranging the wirings M1 (or M2) used for power supply can be secured, and the wirings M1 (or M2) used for power supply can be formed in a plane wiring pattern excluding the region R16′ including the plurality of wirings 16′. The plane wiring pattern may cover almost all the area disposed outside the region R16′. The region R16′, for example, may be configured as a closed area including the plurality of wirings 16′, which is a closed area included in the region R20, on the inside thereof. It should be noted that, on the wiring layers disposed below the uppermost layer, wirings of some degree may be arranged in consideration of electrical characteristics.

As illustrated in FIG. 4, the wirings M1 and M2 of layers disposed below the uppermost layer among the multi-layer wirings 12 used for transmitting power are configured in a plane wiring pattern in the plan view. The plane wiring pattern includes a wiring pattern extending in a plane and, for example, includes a wiring pattern extending in a mesh shape. Accordingly, the combined resistance of the transmission path from the metal wire 40 to the power supply terminal 23 of the logic chip 20 can be easily configured to be low, and thus, a voltage drop at the time of transmitting power can be suppressed.

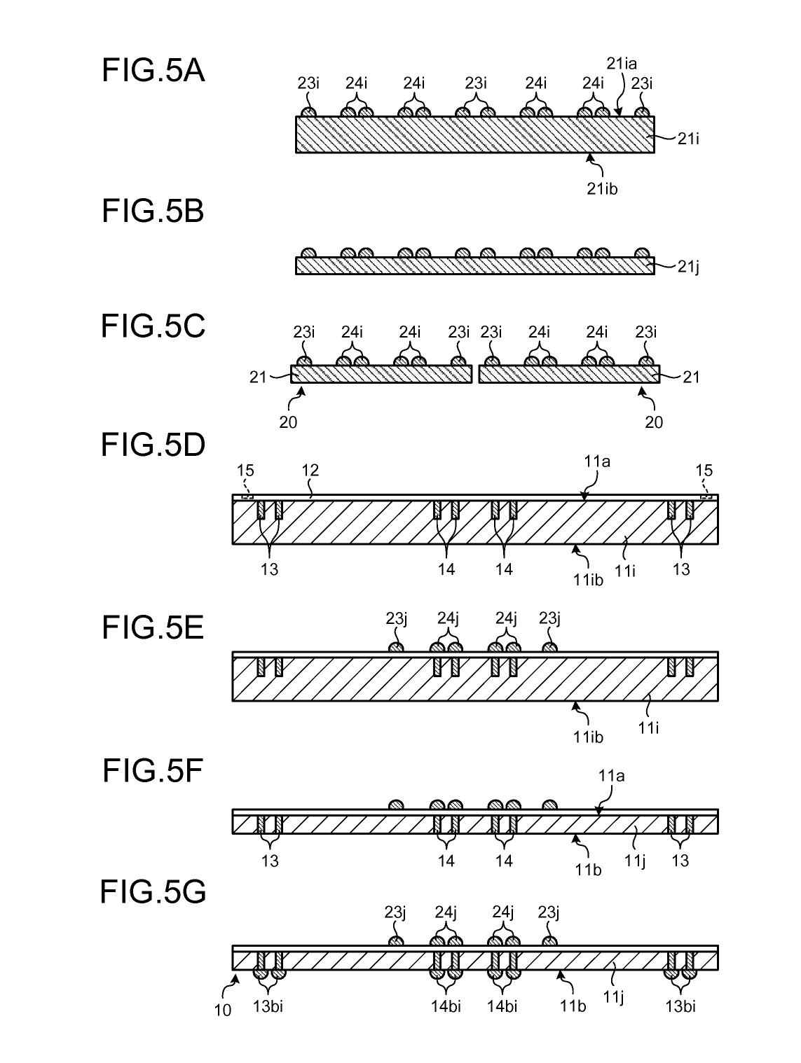

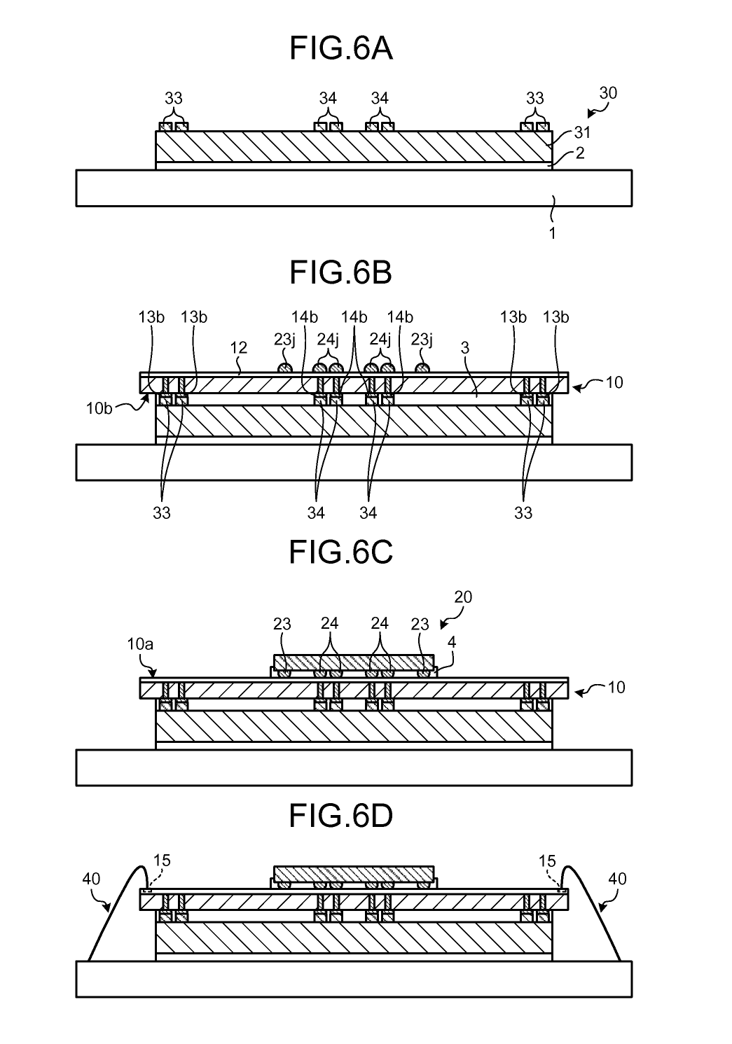

Next, a method of manufacturing the semiconductor device 100 will be described with reference to FIGS. 5A to 5G and FIGS. 6A to 6D. FIGS. 5A to 5G and FIGS. 6A to 6D are process cross-sectional views that illustrate the method of manufacturing the semiconductor device 100.

In the method of manufacturing the semiconductor device 100, processes illustrated in FIG. 5A to 5C and processes illustrated in FIGS. 5D to 5G are performed in a parallel manner, and then, processes illustrated in FIGS. 6A to 6D are performed.

More specifically, in the process illustrated in FIG. 5A, a multi-layer wiring structure is formed on a semiconductor substrate 21i. The semiconductor substrate 21i, for example, is formed by using a material having silicon as its main composition. Power supply terminals 23i and signal terminals 24i are formed on a surface 21ia of the semiconductor substrate 21i. For example, the power supply terminals 23i and the signal terminals 24i are formed at predetermined positions on the surface 21ia of the semiconductor substrate 21i by connecting bumps of conductors of solder or the like.

In the process illustrated in FIG. 5B, a rear surface 21ib of the semiconductor substrate 21i is polished to be thinned, and accordingly, a thinned semiconductor substrate 21j is acquired. As the polishing of the rear surface, mechanical polishing may be performed, and various methods such as physical polishing (dry etching), chemical polishing (wet etching), and chemical mechanical polishing (CMP) may be used. In this way, the thinned semiconductor substrate 21j can be acquired.

In the process illustrated in FIG. 5C, the semiconductor substrate 21j is divided into individual semiconductor chips, whereby a plurality of logic chips 20 are acquired. Each logic chip 20 includes a chip main body 21, a power supply terminal 23i, and a signal terminal 24i.

Although not illustrated in the figures, by performing processes similar to the processes illustrated in FIGS. 5A to 5C, a plurality of memory chips 30 can be acquired.

In the process illustrated in FIG. 5D, a plurality of holes are formed on the surface 11a of the semiconductor substrate 11i by using a dry etching method or the like, and the formed holes are filled up with conductive materials through a plating process or the like, whereby vias 13 and 14 are formed. At this time, each of the vias 13 and 14 may extend from the surface 11a up to a position that is shallower than the rear surface 11ib. Then, a multi-layer wiring structure including multi-layer wirings 12 that are respectively connected to the vias 13 and 14 is formed on the surface 11a of the semiconductor substrate 11i. At this time, the peripheral positions of the uppermost insulating layer are open, and power supply pads 15 and pads 18 used for signals (see FIG. 3) are formed.

In the process illustrated in FIG. 5E, bumps of conductors of solder or the like are connected to regions in which the logic chip 20 is to be mounted, whereby connection end portions 23j and 24j are formed. Each connection end portion 23j is formed at a position corresponding to the power supply terminal 23i in the region in which the logic chip 20 is to be mounted. Each connection end portion 24j is formed at a position corresponding to the signal terminal 24i in the region in which the logic chip 20 is to be mounted.

In the process illustrated in FIG. 5F, the semiconductor substrate 11i is thinned by polishing the rear surface 11ib of the semiconductor substrate 11i until the vias 13 and 14 are exposed. In this way, a thinned semiconductor substrate 11j is acquired. The vias 13 and 14 pass through the thinned semiconductor substrate 11j from the surface 11a thereof to the rear surface 11b.

In the process illustrated in FIG. 5G, bumps of conductors of solder or the like are connected to the vias 13 and 14 exposed to the rear surface 11b of the semiconductor substrate 11j, whereby connection end portions 13bi and 14bi are formed. Then, the semiconductor substrate 11j is divided into individual semiconductor chips, whereby a plurality of interposers 10 are acquired.

In the process illustrated in FIG. 6A, the memory chip 30 is mounted on the package substrate 1. For example, the upper side of the package substrate 1 is coated with a mount resin 2, and the memory chip 30 is arranged on the mount resin 2 such that the power supply terminals 33 and the signal terminals 34 are disposed on the upper side.

In the process illustrated in FIG. 6B, the memory chip 30 is mounted on the second principal surface 10b of the interposer 10. For example, the interposer 10 acquired in the process illustrated in FIG. 5G is arranged on the memory chip 30 such that the multi-layer wiring 12 is disposed on the upper side. At this time, by matching the positions of the interposer 10 and the memory chip 30, the power supply terminals 33 are connected to the connection end portions 13bi, and the signal terminals 34 are connected to the connection end portions 14bi. Then, a gap between the interposer 10 and the memory chip 30 is filled up with a sealing resin 3 so as to be sealed.

In the process illustrated in FIG. 6C, the logic chip 20 is mounted on the first principal surface 10a of the interposer 10. For example, the logic chip 20 acquired in the process illustrated in FIG. 5C is arranged on the interposer 10 such that the power supply terminals 23i and the signal terminals 24i are disposed on the lower side. At this time, by matching the positions of the logic chip 20 and the interposer 10, a power supply terminal 23 is formed by connecting the power supply terminal 23i to the connection end portion 23j, and a signal terminal 24 is formed by connecting the signal terminal 24i to the connection end portion 24j (see FIGS. 5C and 5G). Then, a gap between the logic chip 20 and the interposer 10 is filled up with a sealing resin 4 so as to be sealed.

In the process illustrated in FIG. 6D, the power supply pad 15 of the interposer 10 and the power supply wiring 51 (see FIG. 3) of the package substrate 1 are connected through the metal wire 40. For example, one end of the metal wire 40 is connected to the power supply wiring 51 (see FIG. 3) of the package substrate 1, and the other end of the metal wire 40 is connected to the power supply pad 15 of the interposer 10.

As described above, in the semiconductor device 100 according to the first embodiment, the metal wire 40 is connected to the power supply pad 15. The multi-layer wiring 12 of the interposer 10 electrically connects the power supply pad 15 and the power supply terminal 23 of the logic chip 20 to each other. Accordingly, the combined resistance of a transmission path from the metal wire 40 to the power supply terminal 23 of the logic chip 20 can be configured to be low in an easy manner, and thus, a voltage drop at the time of transmitting power can be suppressed.

In addition, in the first embodiment, the wirings M1 and M2 of layers disposed below the uppermost layer among the multi-layer wirings 12 used for transmitting power are configured in a plane wiring pattern in the plan view. Accordingly, the combined resistance of the transmission path from the metal wire 40 to the power supply terminal 23 of the logic chip 20 can be easily configured to be low.

Furthermore, in the first embodiment, the multi-layer wiring 12 that transmits power makes a parallel connection between the power supply terminal 23 of the logic chip 20 and the metal wire 40 in a stacking direction in the sectional view. Accordingly, the combined resistance of a transmission path from the metal wire 40 to the power supply terminal 23 of the logic chip 20 can be configured to be low in an easy manner.

In addition, in the semiconductor device 100 according to the first embodiment, the plane dimension of the interposer 10 is larger than that of the memory chip 30. Accordingly, the via 13 of the interposer 10 can be easily connected to the power supply terminal 33 located on the periphery of the memory chip 30. Thus, power can be transmitted from the metal wire 40 to the power supply terminal 33 of the memory chip 30 through the multi-layer wiring 12 and the via 13.

Furthermore, in the method of manufacturing the semiconductor device 100 according to the first embodiment, the process of acquiring the logic chips 20 by dividing the semiconductor substrate into individual semiconductor chips, the process of acquiring the interposers 10 by dividing the semiconductor substrate into individual semiconductor chips, and the process of acquiring the memory chips 30 by dividing the semiconductor substrate into individual semiconductor chips can be performed in a parallel manner. Accordingly, a time required for manufacturing the semiconductor device 100 can be shortened in an easy manner.

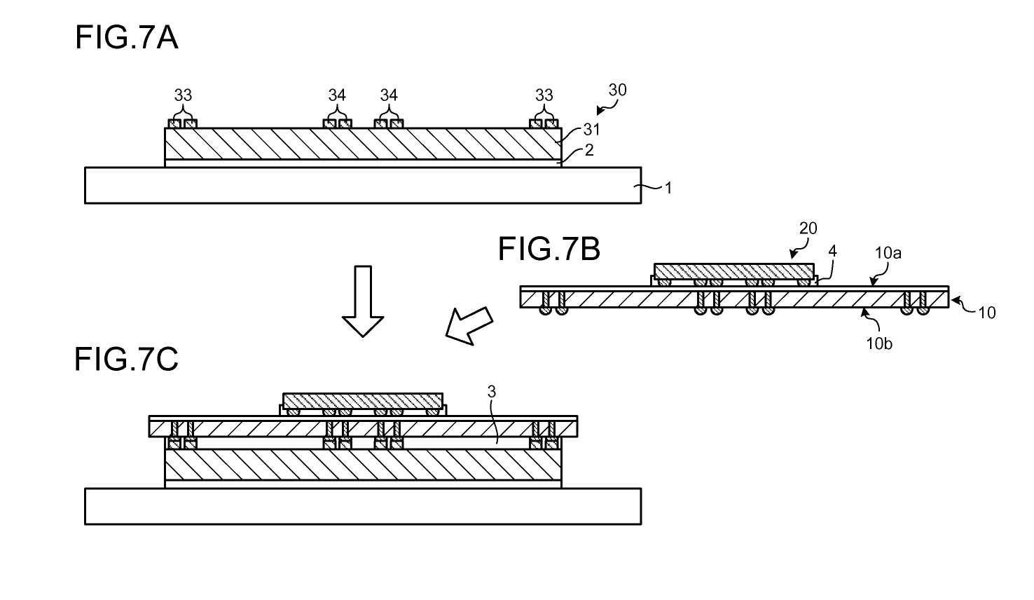

It should be noted that, in the method of manufacturing the semiconductor device 100, instead of the processes illustrated in FIGS. 6A to 6C, processes illustrated in FIGS. 7A to 7C may be performed. In other words, the process illustrated in FIG. 7A and the process illustrated in FIG. 7B are performed in a parallel manner, and then, the process illustrated in FIG. 7C is performed.

In the process illustrated in FIG. 7A, similarly to the process illustrated in FIG. 6A, a memory chip 30 is mounted on a package substrate 1.

In the process illustrated in FIG. 7B, a logic chip 20 is mounted on the first principal surface 10a of the interposer 10, whereby a structure in which the logic chip 20 and the interposer 10 are integrated is formed. For example, the logic chip 20 acquired in the process illustrated in FIG. 5C is arranged on the interposer 10 such that the power supply terminals 23i and the signal terminals 24i are disposed on the lower side. At this time, by matching the positions of the logic chip 20 and the interposer 10, a power supply terminal 23 is formed by connecting the power supply terminal 23i to the connection end portion 23j, and a signal terminal 24 is formed by connecting the signal terminal 24i to the connection end portion 24j (see FIGS. 5C and 5G). Then, a gap between the logic chip 20 and the interposer 10 is filled up with a sealing resin 4 so as to be sealed.

In the process illustrated in FIG. 7C, the structure in which the logic chip 20 and the interposer 10 are integrated is arranged on the memory chip 30, and the memory chip 30 is mounted on the second principal surface 10b of the interposer 10. At this time, by matching the positions of the interposer 10 and the memory chip 30, the power supply terminals 33 are connected to the connection end portions 13bi, and the signal terminals 34 are connected to the connection end portions 14bi. Then, a gap between the interposer 10 and the memory chip 30 is filled up with a sealing resin 3 so as to be sealed.

In this way, the process of mounting the memory chip 30 on the package substrate 1 and the process of mounting the logic chip 20 on the first principal surface 10a of the interposer 10 can be performed in a parallel manner, and accordingly, the time required for manufacturing the semiconductor device 100 can be shortened further in an easy manner.

### Second Embodiment

Next, the semiconductor device 200 according to a second embodiment will be described. Hereinafter, description will be presented focusing on portions different from those of the first embodiment.

In the first embodiment, while, in the cross-sectional view, the parallel connection is made between the power supply terminal 23 of the logic chip 20 and the metal wire 40 in the stacking direction by the multi-layer wiring 12, in the second embodiment, in addition to the multi-layer wiring 12, the parallel connection is made in the stacking direction also by a redistribution 262.

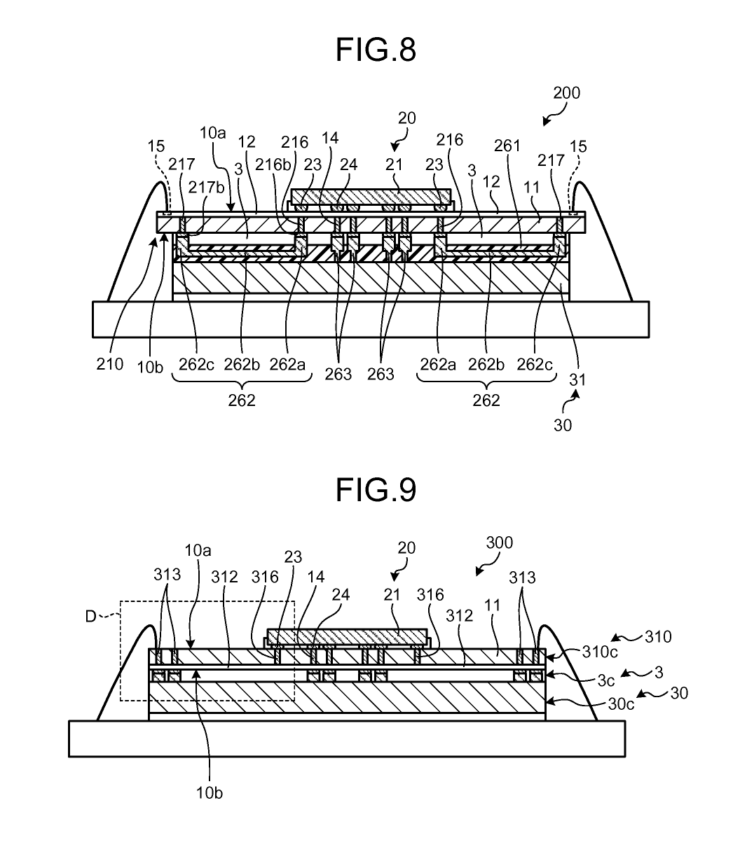

More specifically, the semiconductor device 200, as illustrated in FIG. 8, instead of the interposer 10 (see FIG. 1), includes an interposer 210 and further includes an insulating layer 261 and redistributions 262 and 263. The interposer 210 further includes a via (second via) 216 and a via (third via) 217.

The redistributions 262 and 263 are arranged between the interposer 210 and the memory chip 30. The memory chip 30 is mounted on the second principal surface 10b of the interposer 210 through the redistributions 262 and 263.

The via 216 passes through the substrate 11 from the surface 11a to the rear surface 11b (see FIG. 2). An end portion of the via 216 that is disposed on the first principal surface 10a side is connected to the wiring M1 of the lowermost layer of the multi-layer wiring 12 on the logic chip 20 side (see FIG. 2). An end portion 216b of the via 216 that is disposed on the second principal surface 10b side is connected to the redistribution 262. Accordingly, the via 216 electrically connects the power supply terminal 33 of the memory chip 30 and the redistribution 262 to each other. The via 216, for example, may be formed by using a material having copper as its main composition.

The via 217 passes through the substrate 11 from the surface 11a to the rear surface 11b (see FIG. 2). An end portion of the via 217 that is disposed on the first principal surface 10a side is connected to the wiring M1 of the lowermost layer of the multi-layer wiring 12 on the metal wire 40 side (see FIG. 2). An end portion 217b of the via 217 that is disposed on the second principal surface 10b side is connected to the redistribution 262. Accordingly, the via 217 electrically connects the redistribution 262 and the multi-layer wiring 12 to each other. The via 217, for example, may be formed by using a material having copper as its main composition.

The insulating layer 261 is arranged on the memory chip 30. A gap between the insulating layer 261 and the interposer 210 is sealed using the sealing resin 3. The insulating layer 261, for example, may be formed using a polyimide-based resin.

The redistribution 262 electrically connects the via 216 and the via 217 to each other. The redistribution 262 is insulated from the substrate 11 and the chip main body 31 through the insulating layer 261. The redistribution 262 includes: a plug portion 262a; a line portion 262b; and a plug portion 262c. The plug portion 262a extends from the end portion 216b of the via 216 to the line portion 262b along a direction approximately perpendicular to the second principal surface 10b. The line portion 262b extends from the lower end of the plug portion 262a to the lower end of the plug portion 262c along a direction approximately parallel to the second principal surface 10b. The plug portion 262c extends from the line portion 262b to the end portion 217b of the via 217 along a direction approximately perpendicular to the second principal surface 10b. The redistribution 262, for example, may be formed by using a material having copper as its main composition.

The redistribution 262 is connected to wirings M1 to M3 of a plurality of layers in a parallel manner in the cross-sectional view. In other words, the redistribution 262 is connected to the wiring M3 of the uppermost layer through the via 216, the wiring M1, the plug PL12-1, the wiring M2, and the plug PL23-1 on the logic chip 20 side. The redistribution 262 is connected to the wiring M3 of the uppermost layer through the via 217, the wiring M1, the plug PL12-2, the wiring M2, and the plug PL23-2 on the metal wire 40 side.

The redistribution 263 electrically connects the end portion of the via 14 that is disposed on the second principal surface 10b side to the signal terminal of the memory chip 30.

As described above, in the second embodiment, the redistribution 262 and the multi-layer wiring 12 that transmit power make a parallel connection between the power supply terminal 23 of the logic chip 20 and the metal wire 40 in a stacking direction in the sectional view. Accordingly, the combined resistance of a transmission path from the metal wire 40 to the power supply terminal 23 of the logic chip 20 can be configured to be low in an easy manner.

### Third Embodiment

Next, the semiconductor device 300 according to a third embodiment will be described. Hereinafter, description will be presented focusing on portions different from those of the first embodiment.

In the first embodiment, while the plane dimension of the interposer 10 is larger than that of the memory chip 30, in the third embodiment, the plane dimension of the interposer 10 is the same as that of the memory chip 30.

More specifically, the semiconductor device 300, as illustrated in FIG. 9, includes an interposer 310 instead of the interposer 10 (see FIG. 1). The plane dimension of the interposer 310 is the same as that of the memory chip 30. In the case of being projected in a direction perpendicular to the first principal surface 10a, the interposer 310 matches the memory chip 30. A side face 310c of the interposer 310, a side face 3c of the sealing resin 3, and a side face 30c of the memory chip 30 form an approximately continuous face.

The interposer 310 includes a multi-layer wiring 312 and a via 313 instead of the multi-layer wiring 12 and the via 13 (see FIG. 1) and further includes a via 316.

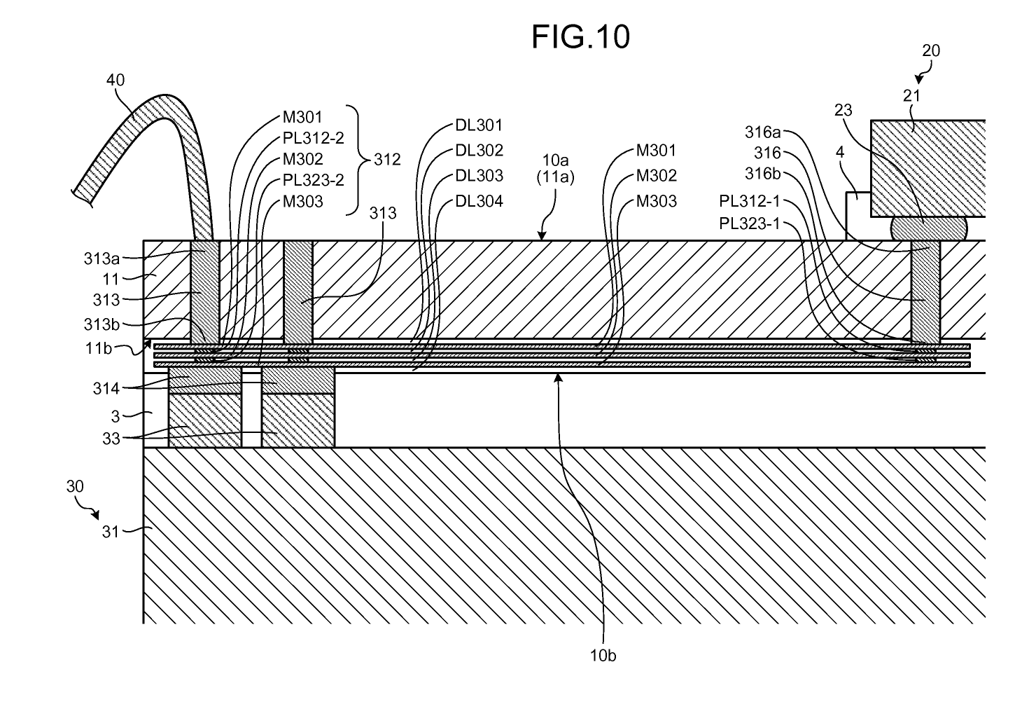

The multi-layer wiring 312 is disposed on the second principal surface 10b side of the substrate 11. The multi-layer wiring 312 electrically connects the via 316 and the via 313 to each other. For example, the multi-layer wiring 312, as illustrated in FIG. 10, includes wirings M301 to M303 of a plurality of layers and a plurality of plugs PL312-1, PL323-1, PL312-2, and PL323-2. FIG. 10 is an enlarged cross-sectional view that illustrates the configuration of the multi-layer wiring 312 and an enlarged cross-sectional view of a portion D represented in FIG. 9. The wiring M303 of the lowermost layer among the wirings M301 to M303 of the plurality of layers is connected to the power supply terminal 23 of the logic chip 20 through the via 316 on the logic chip 20 side and is connected to the via 313 on the metal wire 40 side. Each of the wirings M301 to M303 of the plurality of layers, for example, may be formed using a material having aluminum as its main composition. Each of the plurality of plugs PL312-1, PL323-1, PL312-2, and PL323-2, for example, may be formed using a material having tungsten as its main composition.

The wirings M302 and M301 of layers higher than the lowermost layer of the wirings M301 to M303 of the plurality of layers are connected to the wiring M303 of the lowermost layer in parallel therewith in the sectional view. In other words, the wiring M302 is connected to the wiring M303 of the lowermost layer through the plug PL323-1 on the logic chip 20 side. In addition, the wiring M302 is connected to the wiring M303 of the lowermost layer through the plug PL323-2 on the metal wire 40 side. The wiring M301 is connected to the wiring M303 of the lowermost layer through the plug PL312-1, the wiring M302, and the plug PL323-1 on the logic chip 20 side. In addition, the wiring M301 is connected to the wiring M303 of the lowermost layer through the plug PL312-2, the wiring M302, and the plug PL323-2 on the metal wire 40 side.

It should be noted that, on the rear surface 11b of the substrate 11, a multi-layer wiring structure in which the insulating layers DL301 to DL304 and the wirings M301 to M303 are alternately stacked a plurality of times is formed.

The via 316 passes through the substrate 11 from the surface 11a to the rear surface 11b. An end portion 316a of the via 316 that is disposed on the first principal surface 10a side is connected to the power supply terminal 23 of the logic chip 20. An end portion 316b of the via 316 that is disposed on the second principal surface 10b side is connected to wiring M301 of the uppermost layer of the multi-layer wiring 312. Accordingly, the via 316 electrically connects the power supply terminal 23 of the logic chip 20 and the multi-layer wiring 312 to each other.

The via 313 passes through the substrate 11 from the surface 11a to the rear surface 11b. The metal wire 40 is connected to an end portion 313a of the via 313 that is disposed on the first principal surface 10a side. An end portion 313b of the via 313 that is disposed on the second principal surface 10b side is connected to wiring M301 of the uppermost layer of the multi-layer wiring 312. Accordingly, the via 313 electrically connects the multi-layer wiring 312 and the metal wire 40 to each other.

The via 313, in the case of being projected in a direction perpendicular to the first principal surface 10a, is located on the inner side of the memory chip 30. The via 313, for example, can be arranged at a position corresponding to the power supply terminal 33 of the memory chip 30.

It should be noted that, the power supply terminal 33 of the memory chip 30 is connected to the wiring M303 of the lowermost layer of the multi-layer wiring 312 through the electrode 314. The electrode 314, for example, is formed by using a material having copper as its main composition.

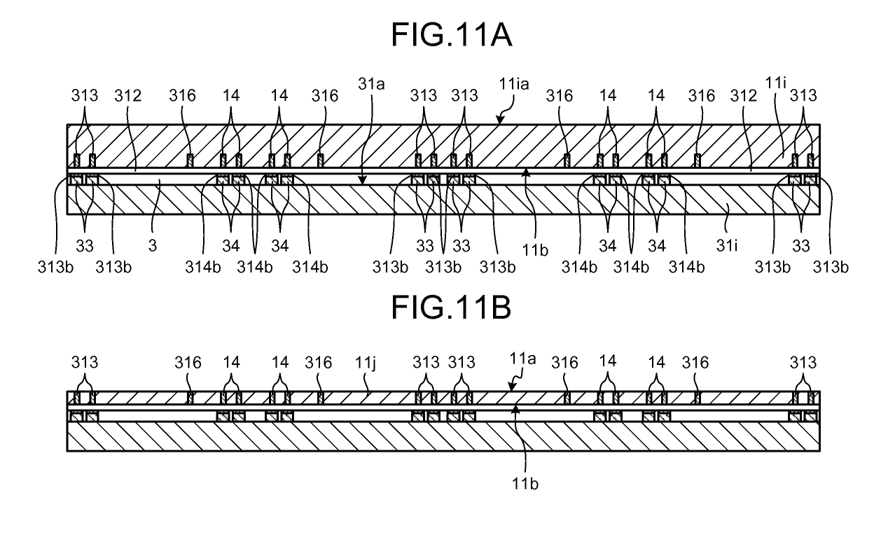

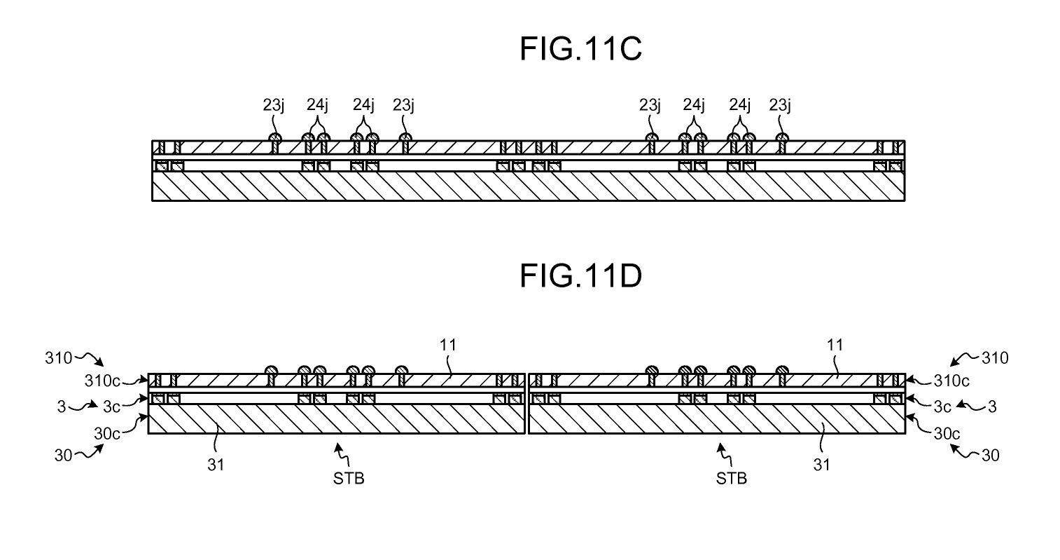

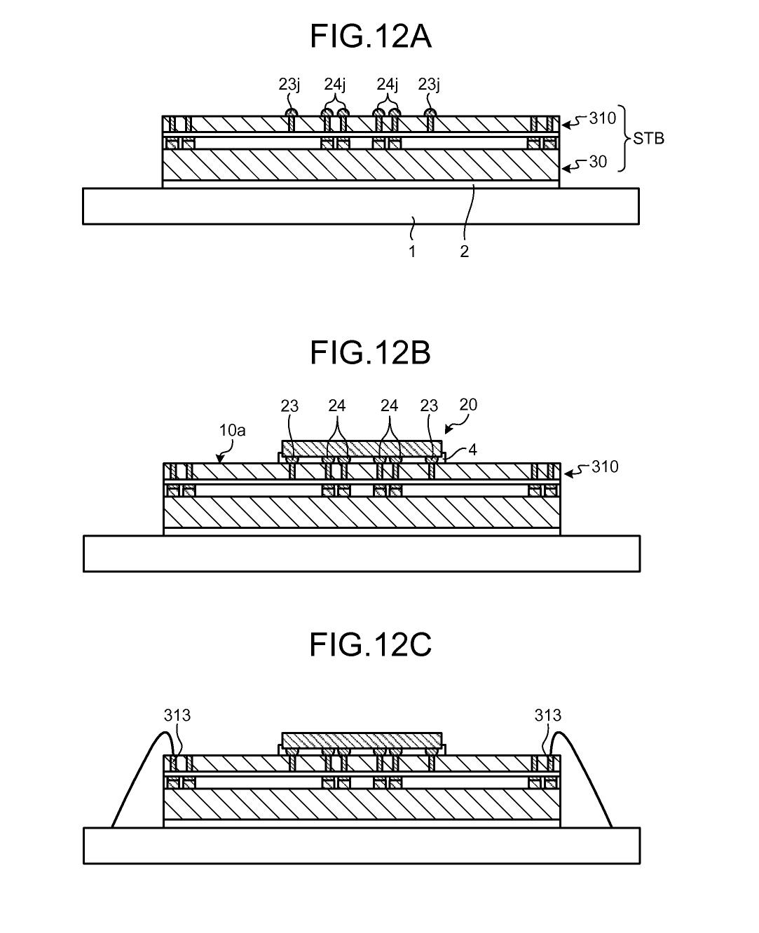

In addition, a method of manufacturing the semiconductor device 300, as illustrated in FIGS. 11A to 11D and FIGS. 12A to 12C, is different from that of the first embodiment in the following points. FIGS. 11A to 11D and FIGS. 12A to 12C are process cross-sectional views that illustrate the method of manufacturing the semiconductor device 300.

In the method of manufacturing the semiconductor device 100, processes illustrated in FIG. 5A to 5C and processes illustrated in FIGS. 11A to 11D are performed in a parallel manner, and then, processes illustrated in FIGS. 12A to 12C are performed.

In the process illustrated in FIG. 11A, a semiconductor substrate 11i to be the interposer 310 and a semiconductor substrate 31i to be the memory chip 30 are bonded together.

For example, a plurality of holes are formed in the rear surface 11b of the semiconductor substrate 11i by using a dry etching method or the like, and the formed holes are filled up with a conductive material through a plating process or the like, whereby vias 313, 316, and 14 are formed. At this time, each of the vias 313, 316, and 14 may extend from the rear surface 11b up to a position that is shallower than the surface 11a. Then, a multi-layer wiring structure including multi-layer wirings 312 that are respectively connected to the vias 313, 316, and 14 is formed on the rear surface 11b of the semiconductor substrate 11i. In addition, electrodes 313b and 314b are formed at predetermined positions on the multi-layer wiring 312.

In parallel with the formation of the vias 313, 316, and 14 and the multi-layer wiring structure for the semiconductor substrate 11i, a multi-layer wiring structure is formed in the semiconductor substrate 31i. In addition, power supply terminals 33 and signal terminals 34 are formed on the surface 31a of the semiconductor substrate 31i. For example, bumps of conductors of solder or the like are connected to predetermined positions on the surface 31a of the semiconductor substrate 31i, whereby the power supply terminals 33 and the signal terminals 34 are formed.

Then, the semiconductor substrate 11i and the semiconductor substrate 31i are arranged such that the rear surface 11b of the semiconductor substrate 11i and the surface 31a of the semiconductor substrate 31i face each other. At this time, by matching the positions of the semiconductor substrates 11i and 31i, the power supply terminals 33 are connected to the electrodes 313b, and the signal terminals 34 are connected to the electrodes 314b. Then, a gap between the semiconductor substrate 11i and the semiconductor substrate 31i is filled up with the sealing resin 4 so as to be sealed.

In the process illustrated in FIG. 11B, the semiconductor substrate 11i is thinned by polishing the surface 11a of the semiconductor substrate 11i until the vias 313, 316, and 14 are exposed. In this way, a thinned semiconductor substrate 11j is acquired. The vias 313, 316, and 14 pass through the thinned semiconductor substrate 11j from the surface 11a thereof to the rear surface 11b.

In the process illustrated in FIG. 11C, bumps of conductors of solder or the like are connected to regions in which the logic chip 20 is to be mounted, whereby connection end portions 23j and 24j are formed. Each connection end portion 23j is formed at a position, at which the via 316 is exposed in the region in which the logic chip 20 is to be mounted, corresponding to the power supply terminal 23i. Each connection end portion 24j is formed at a position, at which the via 14 is exposed in the region in which the logic chip 20 is to be mounted, corresponding to the signal terminal 24i.

In the process illustrated in FIG. 11D, the substrate acquired by bonding the semiconductor substrate 11j and the semiconductor substrate 31i together is divided into individual semiconductor chips, whereby a plurality of stacked bodies STB are acquired. In each stacked body STB, the interposer 310 is stacked on the memory chip 30, and the plane dimension of the interposer 310 is the same as that of the memory chip 30. For example, the side face 310c of the interposer 10 and the side face 30c of the memory chip 30 form an approximately continuous face.

In the process illustrated in FIG. 12A, the stacked body STB is mounted on the package substrate 1. For example, the upper side of the package substrate 1 is coated with a mount resin 2, and the stacked body STB is arranged on the mount resin 2 such that the connection end portions 23j and 24j are disposed on the upper side (in other words, the interposer 310 is disposed on the upper side, and the memory chip 30 is disposed on the lower side).

In the process illustrated in FIG. 12B, the logic chip 20 is mounted on the first principal surface 10a of the interposer 310. For example, the logic chip 20 acquired in the process illustrated in FIG. 5C is arranged on the interposer 310 such that the power supply terminals 23i and the signal terminals 24i are disposed on the lower side. At this time, by matching the positions of the logic chip 20 and the interposer 310, the power supply terminal 23i is connected to the connection end portion 23j so as to form the power supply terminal 23, and the signal terminal 24i is connected to the connection end portion 24j so as to form the signal terminal 24 (see FIG. 5C and FIG. 12A). Then, a gap between the logic chip 20 and the interposer 310 is filled up with the sealing resin 4 so as to be sealed.

In the process illustrated in FIG. 12C, the via 313 of the interposer 310 and the power supply wiring 51 (see FIG. 3) of the package substrate 1 are connected through the metal wire 40. For example, one end of the metal wire 40 is connected to the power supply wiring 51 (see FIG. 3) of the package substrate 1, and the other end of the metal wire 40 is connected to the via 313 of the interposer 310.

As described above, in the semiconductor device 300 according to the third embodiment, the metal wire 40 is connected to the via 313. The multi-layer wiring 312 of the interposer 310 electrically connects the via 313 to the power supply terminal 23 of the logic chip 20 through the via 316. Accordingly, the combined resistance of the transmission path from the metal wire 40 to the power supply terminal 23 of the logic chip 20 can be easily configured to be low, and thus, a voltage drop at the time of transmitting power to the logic chip 20 can be suppressed.

In addition, in the semiconductor device 300 according to the third embodiment, the plane dimension of the interposer 310 is the same as that of the memory chip 30. The via 313, for example, may be arranged at a position corresponding to the power supply terminal 33 of the memory chip 30. In this way, since the path length from the via 313 to the power supply terminal 33 can be shortened in an easy manner, the resistance of the transmission path from the metal wire 40 to the power supply terminal 33 of the memory chip 30 can be easily configured to be low, and thus, a voltage drop at the time of transmitting power to the memory chip 30 can be suppressed.

Furthermore, in the method of manufacturing the semiconductor device 300 according to the third embodiment, the process of acquiring the interposer 310 by dividing the semiconductor substrate 11j into individual semiconductor chips and the process of acquiring the memory chip 30 by dividing the semiconductor substrate 31i into individual semiconductor chips can be performed at the same time. Accordingly, a time required for manufacturing the semiconductor device 300 can be easily shortened, and the number of manufacturing processes of the semiconductor device 300 can be decreased, whereby the manufacturing cost of the semiconductor device 300 can be reduced.

It should be noted that, in the method of manufacturing the semiconductor device 300 according to the third embodiment, while a method has been described as an example in which, after the vias 313, 316, and 14 are formed in the semiconductor substrate 11i, the semiconductor substrate 11i and the semiconductor substrate 31i are bonded together, it may be configured such that, after the semiconductor substrate 11i and the semiconductor substrate 31i are bonded together, the vias 313, 316, and 14 are formed in the semiconductor substrate 11i.

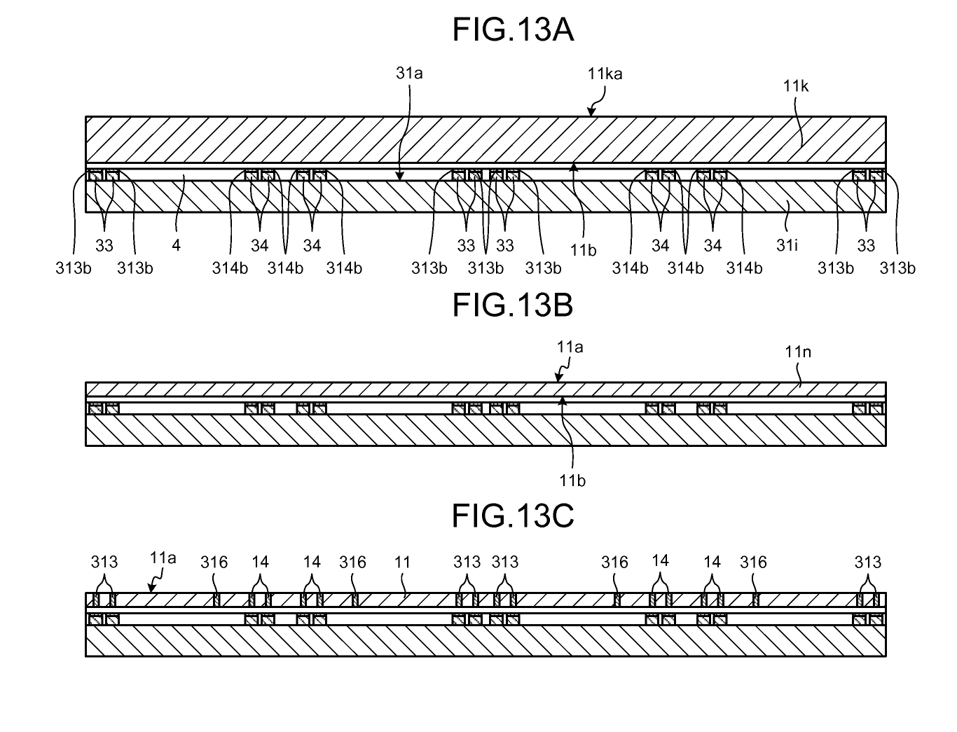

For example, in the method of manufacturing the semiconductor device 300, instead of the processes illustrated in FIGS. 11A to 11B, processes illustrated in FIGS. 13A to 13C may be performed.

In the process illustrated in FIG. 13A, a semiconductor substrate 11k to be the interposer 310 and a semiconductor substrate 31i to be the memory chip 30 are bonded together.

For example, a multi-layer wiring structure including the multi-layer wiring 312 is formed on the rear surface 11b of the semiconductor substrate 11k. In addition, electrodes 313b and 314b are formed at predetermined positions on the multi-layer wiring 312.

In parallel with the formation of the multi-layer wiring structure for the semiconductor substrate 11k, a multi-layer wiring structure is formed in the semiconductor substrate 31i. In addition, power supply terminals 33 and signal terminals 34 are formed on the surface 31a of the semiconductor substrate 31i. For example, bumps of conductors of solder or the like are connected to predetermined positions on the surface 31a of the semiconductor substrate 31i, whereby the power supply terminals 33 and the signal terminals 34 are formed.

Then, the semiconductor substrate 11k and the semiconductor substrate 31i are arranged such that the rear surface 11b of the semiconductor substrate 11k and the surface 31a of the semiconductor substrate 31i face each other. At this time, by matching the positions of the semiconductor substrates 11k and 31i, the power supply terminals 33 are connected to the electrodes 313b, and the signal terminals 34 are connected to the electrodes 314b. Then, a gap between the semiconductor substrate 11k and the semiconductor substrate 31i is filled up with the sealing resin 4 so as to be sealed.

In the process illustrated in FIG. 13B, the semiconductor substrate 11k is thinned up to a predetermined thickness by polishing the surface 11ka of the semiconductor substrate 11k. In this way, a thinned semiconductor substrate 11n is acquired.

In the process illustrated in FIG. 13C, vias 313, 316, and 14 are formed in the thinned semiconductor substrate 11n. For example, a plurality of holes are formed in the surface 11a of the semiconductor substrate 11n by using a dry etching method or the like. At this time, the etching process may be performed until the wiring M1 of the uppermost layer of the multi-layer wiring 312 is exposed. Then, the formed holes are filled up with a conductive material, whereby vias 313, 316, and 14 are formed. In this way, the vias 313, 316, and 14 connected to the multi-layer wiring 312 are formed.

As described above, since the vias 313, 316, and 14 are formed in the semiconductor substrate 11i after the semiconductor substrate 11k and the semiconductor substrate 31i are bonded together, the vias 313, 316, and 14 can be easily positioned with respect to the power supply terminals 33 and the signal terminals 34 of the semiconductor substrate 31i.

### Fourth Embodiment

Next, the semiconductor device 400 according to a fourth embodiment will be described. Hereinafter, description will be presented focusing on portions different from those of the first embodiment.

In the first embodiment, while the plane dimension of the interposer 10 is larger than that of the memory chip 30, in the fourth embodiment, the plane dimension of the interposer 410 is the same as that of the memory chip 30.

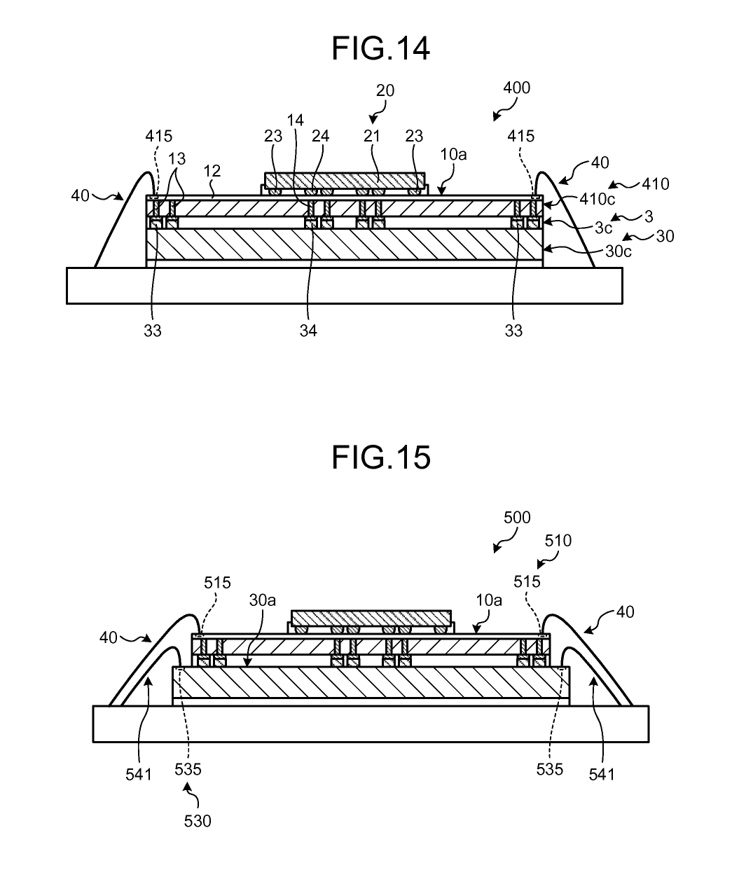

More specifically, the semiconductor device 400, as illustrated in FIG. 14, includes an interposer 410 instead of the interposer 10 (see FIG. 1). The plane dimension of the interposer 410 is the same as that of the memory chip 30. In the case of being projected in a direction perpendicular to the first principal surface 10a, the interposer 410 matches the memory chip 30. A side face 410c of the interposer 410, a side face 3c of the sealing resin 3, and a side face 30c of the memory chip 30 form an approximately continuous face.

The interposer 410 includes a power supply pad 415 instead of the power supply pad 15 (see FIG. 1). The power supply pad 415, in the case of being projected in a direction perpendicular to the first principal surface 10a of the interposer 410, is located on the inner side of the memory chip 30. The power supply pad 415, for example, may be arranged at a position corresponding to the power supply terminal 33 of the memory chip 30.

As described above, in the semiconductor device 400 according to the fourth embodiment, the plane dimension of the interposer 410 is the same as that of the memory chip 30. The power supply pad 415, in the case of being projected in a direction perpendicular to the first principal surface 10a of the interposer 410, is located on the inner side of the memory chip 30. In this way, since the path length from the metal wire 40 to the power supply terminal 23 of the logic chip 20 can be shortened in an easy manner, the resistance of the transmission path from the metal wire 40 to the power supply terminal 23 of the logic chip 20 can be easily configured to be low. As a result, a voltage drop at the time of transmitting power to the logic chip 20 can be suppressed.

In addition, in the semiconductor device 400 according to the fourth embodiment, the power supply pad 415, for example, may be arranged at a position corresponding to the power supply terminal 33 of the memory chip 30. Accordingly, the power supply pad 415 can be easily connected to the power supply terminal 33 of the memory chip 30 through the via 13. In addition, the path length from the power supply pad 415 to the power supply terminal 33 can be shortened in an easy manner, and the resistance of the transmission path from the metal wire 40 to the power supply terminal 33 of the memory chip 30 can be easily configured to be low. Accordingly, a voltage drop at the time of transmitting power to the memory chip 30 can be suppressed.

### Fifth Embodiment

Next, a semiconductor device 500 according to a fifth embodiment will be described. Hereinafter, description will be presented focusing on portions different from those of the first embodiment.

In the first embodiment, while the plane dimension of the interposer 10 is larger than that of the memory chip 30, in the fifth embodiment, the plane dimension of an interposer 510 is smaller than that of the memory chip 30.

More specifically, the semiconductor device 500, as illustrated in FIG. 15, includes the interposer 510 and a memory chip 530 instead of the interposer 10 and the memory chip 30 (see FIG. 1) and further includes a metal wire 541. The plane dimension of the interposer 510 is smaller than that of the memory chip 530. In the case of being projected in a direction perpendicular to the first principal surface 10a, the interposer 510 is included in the memory chip 530. The interposer 510, in the case of being seen in a direction perpendicular to the first principal surface 10a, is arranged on the inner side of the memory chip 530.

The memory chip 530 further includes a power supply pad 535. The power supply pad 535 is disposed on the surface 30a side of the memory chip 530. The power supply pad 535 is located on the peripheral side of the surface 30a.

The metal wire 541 is connected to the power supply pad 535. In other words, a part of the uppermost conduction layer of the multi-layer wiring structure of the memory chip 530 is disposed as the power supply pad 535, and a portion of the uppermost insulating layer that corresponds to the power supply pad 535 is open so as to expose the surface of the power supply pad 535. The metal wire 541 is connected to the exposed surface of the power supply pad 535 through an alloyed junction or the like. For example, the power supply pad 535 is connected to the power supply wiring 51 (see FIG. 3) on the package substrate 1 through the metal wire 541.

The interposer 510 includes a power supply pad 515 instead of the power supply pad 15 (see FIG. 1). The power supply pad 515, in the case of being projected in a direction perpendicular to the first principal surface 10a of the interposer 510, is located on the inner side of the memory chip 530. The power supply pad 515, for example, is arranged on the inner side further than the power supply pad 535 of the memory chip 530.

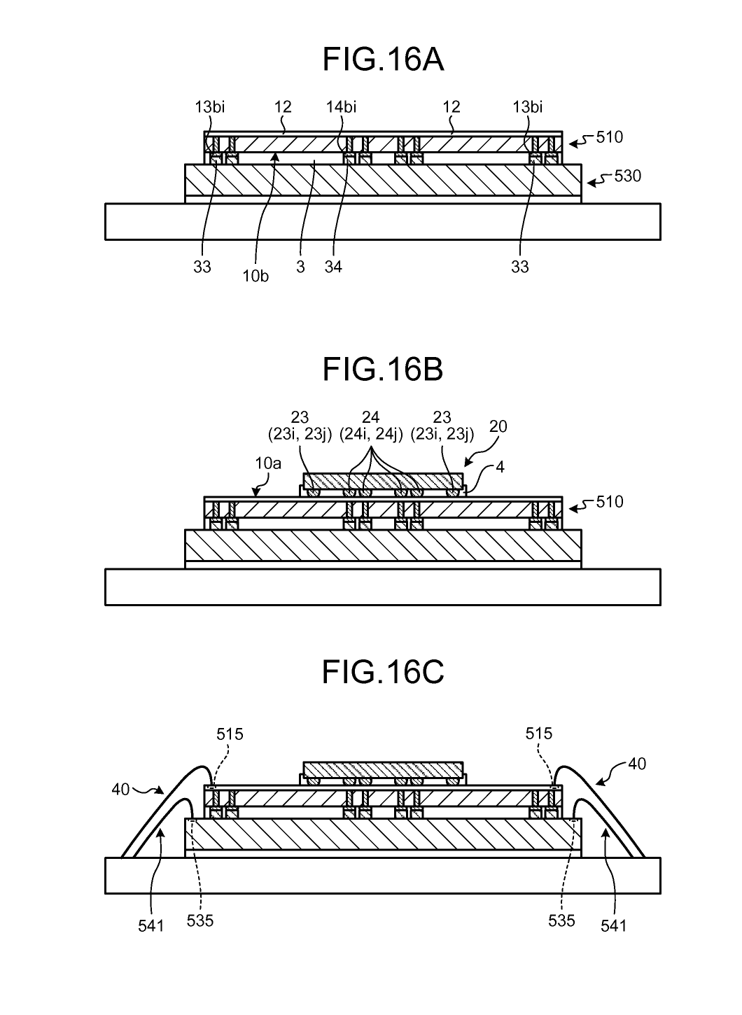

In addition, a method of manufacturing the semiconductor device 500, as illustrated in FIGS. 16A to 16C, is different from that of the first embodiment in the following points. FIGS. 16A to 16C are process cross-sectional views that illustrate the method of manufacturing the semiconductor device 500.

In the method of manufacturing the semiconductor device 500, processes illustrated in FIG. 16A to 16C are performed instead of the processes illustrated in FIGS. 6B to 6D.

In the process illustrated in FIG. 16A, the memory chip 530 is mounted on the second principal surface 10b of the interposer 510. For example, the interposer 510 acquired in a process corresponding to the process illustrated in FIG. 5G is arranged on the memory chip 530 such that the multi-layer wiring 12 is disposed on the upper side. At this time, by matching the positions of the interposer 510 and the memory chip 530, the power supply terminals 33 are connected to the connection end portions 13bi, and the signal terminals 34 are connected to the connection end portions 14bi (see FIG. 5G). Then, a gap between the interposer 510 and the memory chip 530 is filled up with the sealing resin 3 so as to be sealed.

In the process illustrated in FIG. 16B, the logic chip 20 is mounted on the first principal surface 10a of the interposer 510. For example, the logic chip 20 acquired in the process illustrated in FIG. 5C is arranged on the interposer 510 such that the power supply terminals 23i and the signal terminals 24i are disposed on the lower side. At this time, by matching the positions of the logic chip 20 and the interposer 510, a power supply terminal 23 is formed by connecting the power supply terminal 23i to the connection end portion 23j, and a signal terminal 24 is formed by connecting the signal terminal 24i to the connection end portion 24j (see FIGS. 5C and 5G). Then, a gap between the logic chip 20 and the interposer 510 is filled up with the sealing resin 4 so as to be sealed.

In the process illustrated in FIG. 16C, the power supply pad 515 of the interposer 510 and the power supply wiring 51 (see FIG. 3) of the package substrate 1 are connected through the metal wire 40. For example, one end of the metal wire 40 is connected to the power supply wiring 51 (see FIG. 3) of the package substrate 1, and the other end of the metal wire 40 is connected to the power supply pad 515 of the interposer 510.

In addition, the power supply pad 535 of the memory chip 530 and the power supply wiring 51 (see FIG. 3) of the package substrate 1 are connected through the metal wire 541. For example, one end of the metal wire 541 is connected to the power supply wiring 51 (see FIG. 3) of the package substrate 1, and the other end of the metal wire 541 is connected to the power supply pad 535 of the memory chip 530.

As described above, in the semiconductor device 500 according to the fifth embodiment, the plane dimension of the interposer 510 is smaller than that of the memory chip 530. Accordingly, the power supply pads 515 and 535 can be arranged on the interposer 510 and the memory chip 530 respectively, and the metal wires 40 and 541 can be respectively connected to the power supply pads 515 and 535. As a result, the impedance for each of the power supplies of the logic chip 20 and the memory chip 530 can be lowered, and a case can be easily responded in which the types of the power supplies of the logic chip 20 and the memory chip 530 are different from each other.

In addition, in the semiconductor device 500 according to the fifth embodiment, the power supply pad 515, in the case of being projected in a direction perpendicular to the first principal surface 10a of the interposer 510, is located on the inner side of the memory chip 530. The power supply pad 515, for example, is arranged on the inner side further than the power supply pad 535 of the memory chip 530. In this way, the path length from the metal wire 40 to the power supply terminal 23 of the logic chip 20 can be shortened in an easy manner, and the resistance of the transmission path from the metal wire 40 to the power supply terminal 23 of the logic chip 20 can be easily configured to be low. As a result, a voltage drop at the time of transmitting power to the logic chip 20 can be suppressed.

### Sixth Embodiment

Next, a semiconductor device 600 according to a sixth embodiment will be described. Hereinafter, description will be presented focusing on portions different from those of the first embodiment.

In the first embodiment, while the interposer 10 is connected to the package substrate 1 through a wire bonding connection, in the sixth embodiment, an interposer 610 is connected to the package substrate 1 through a flip chip connection.

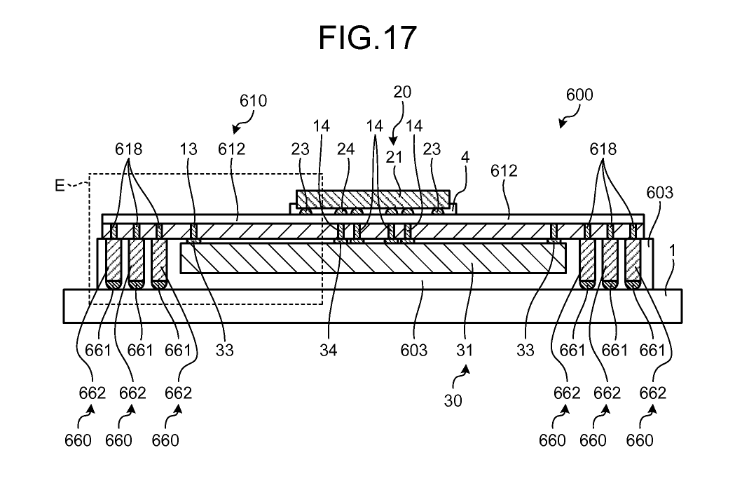

More specifically, the semiconductor device 600, as illustrated in FIG. 17, includes the interposer 610 instead of the interposer 10 (see FIG. 1) and further includes metal pillars 660. The interposer 610 is connected to the package substrate 1 through the metal pillars 660 by using the flip chip connection. The height of the metal pillars 660 is larger than the thickness of the memory chip 30. The plane dimension of the interposer 610 is larger than that of the memory chip 30. In the case of being projected in a direction perpendicular to the first principal surface 10a, the interposer 610 is included in the memory chip 30. Gaps between the interposer 610, the memory chip 30, and the package substrate 1 are sealed using a sealing resin 603. In this structure, the memory chip 30 does not have the mount resin 2 (see FIG. 2) being interposed between the package substrate 1 and the memory chip 30 and can be separated from the package substrate 1 through the sealing resin 603. Accordingly, by using a resin (for example, a silicone resin) having better (higher) thermal conductivity than that of the sealing resin (first sealing member) 4 and that of the mount resin 2 as the sealing resin (second sealing member) 603, an advantageous structure in the viewpoint of heat radiation from the memory chip 30 can be formed.

The interposer 610 includes a multi-layer wiring 612 instead of the multi-layer wiring 12 (see FIG. 1) and further includes a via (fourth via) 618.

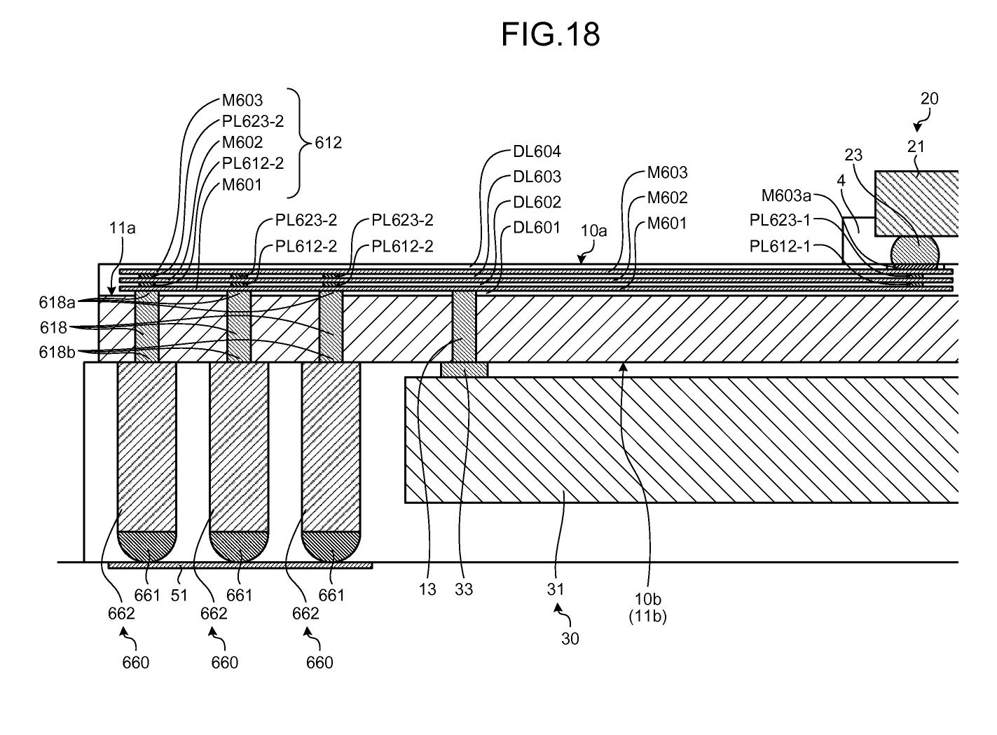

The multi-layer wiring 612 is disposed on the first principal surface 10a side of the substrate 11. The multi-layer wiring 612 electrically connects the power supply terminal 23 of the logic chip 20 and the via 618 to each other. For example, the multi-layer wiring 612, as illustrated in FIG. 18, includes wirings M601 to M603 of a plurality of layers and a plurality of plugs PL612-1, PL623-1, PL612-2, and PL623-2. The wiring M603 of the uppermost layer among the wirings M601 to M603 of the plurality of layers is connected to the power supply terminal 23 of the logic chip 20 through a junction layer M603a on the logic chip 20 side and is connected to the via 618 on the metal wire 40 side. Each of the wirings M601 to M603 of the plurality of layers, for example, may be formed using a material having aluminum as its main composition. Each of the plurality of plugs PL612-1, PL623-1, PL612-2, and PL623-2, for example, may be formed using a material having tungsten as its main composition. The junction layer M603a, for example, is formed by using a material having copper at its main composition.

The wirings M602 and M601 of layers lower than the uppermost layer of the wirings M601 to M603 of the plurality of layers is connected to the wiring M603 of the uppermost layer in parallel therewith in the sectional view. In other words, the wiring M602 is connected to the wiring M603 of the uppermost layer through the plug PL623-1 on the logic chip 20 side. In addition, the wiring M602 is connected to the wiring M603 of the uppermost layer through the plug PL623-2 on the metal wire 40 side. The wiring M601 is connected to the wiring M603 of the uppermost layer through the plug PL612-1, the wiring M602, and the plug PL623-1 on the logic chip 20 side. In addition, the wiring M603 is connected to the wiring M603 of the uppermost layer through the plug PL612-2, the wiring M602, and the plug PL623-2 on the metal wire 40 side.

It should be noted that, on the surface 11a of the substrate 11, a multi-layer wiring structure in which the insulating layers DL601 to DL604 and the wirings M601 to M603 are alternately stacked a plurality of times is formed.

The via 618 passes through the substrate 11 from the surface 11a to the rear surface 11b. An end portion 618a of the via 618 that is disposed on the first principal surface 10a side is connected to the wiring M601 of the lowermost layer of the multi-layer wiring 612. The metal pillars 660 are connected to end portions 618b of the vias 618 that are disposed on the second principal surface 10b side. Accordingly, the via 618 electrically connects the multi-layer wiring 612 and the metal pillars 660 to each other.

The metal pillar 660 electrically connects the via 618 and the power supply wiring 51 to each other. The metal pillar 660 includes a main body portion 662 and an electrode portion 661. The main body portion 662 has a pillar shape and, for example, has a cylinder shape or a prism shape. The main body portion 662, for example, is formed using a material having copper as its main composition. An upper end of the main body portion 662 is connected to the end portion 618b of the via 618 that is disposed on the second principal surface 10b side. A lower end of the main body portion 662 is connected to the electrode portion 661. The electrode portion 661, for example, is formed using solder. The electrode portion 661 is connected to the power supply wiring 51.

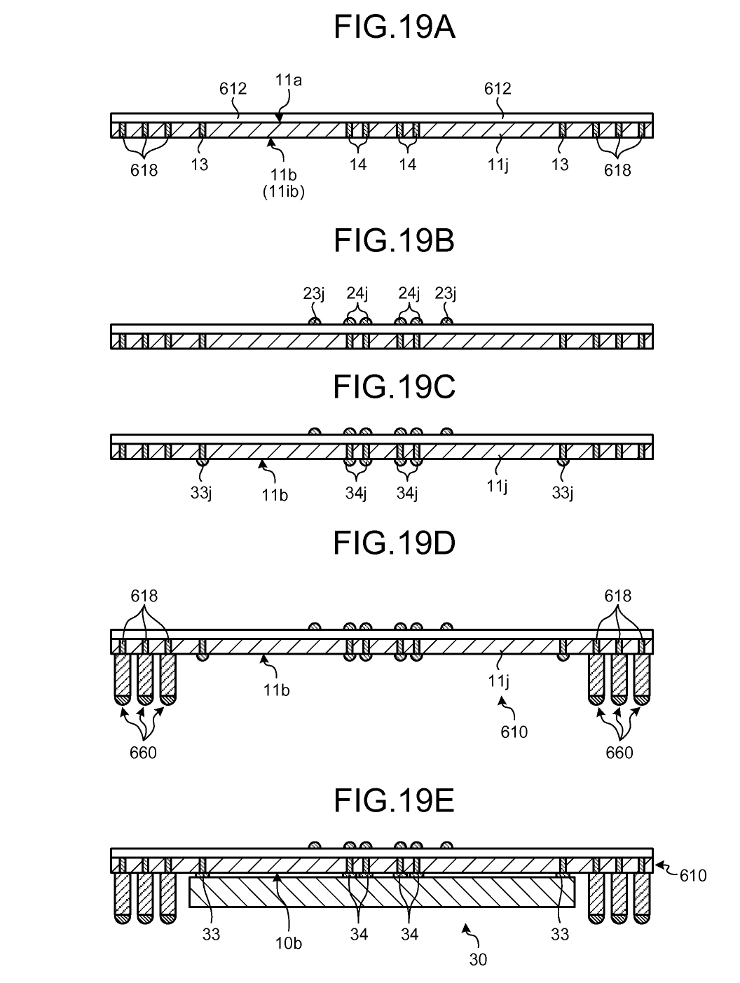

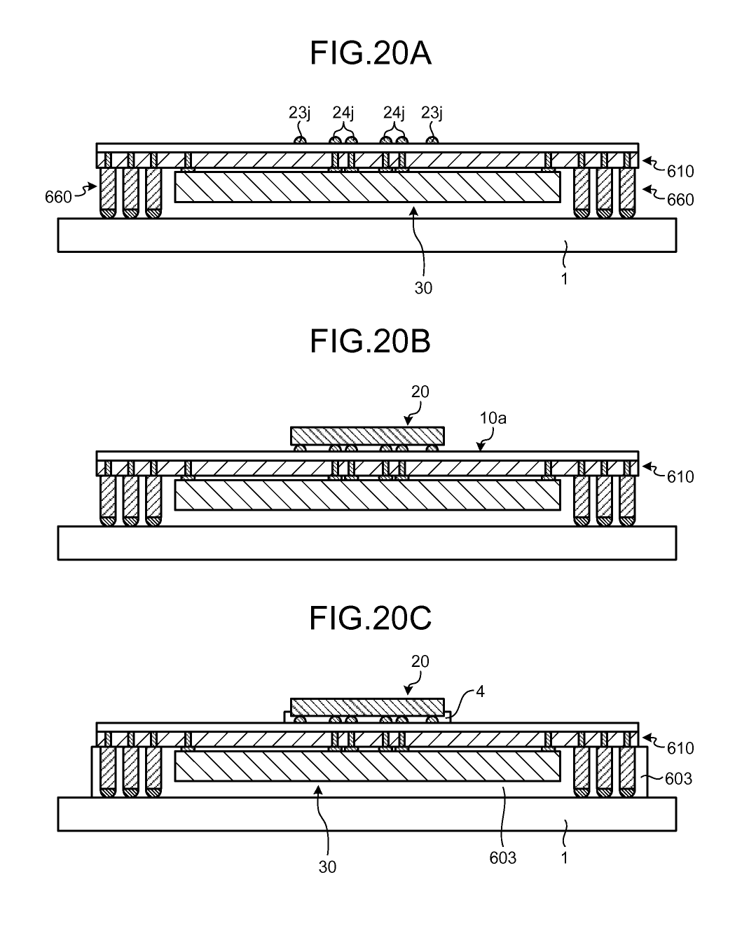

In addition, a method of manufacturing the semiconductor device 600, as illustrated in FIGS. 19A to 19E and FIGS. 20A to 20C, is different from that of the first embodiment in the following points. FIGS. 19A to 19E and FIGS. 20A to 20C are process cross-sectional views that illustrate the method of manufacturing the semiconductor device 600.

In the method of manufacturing the semiconductor device 600, the processes illustrated in FIG. 5A to 5C and processes illustrated in FIGS. 19A to 19D are performed in a parallel manner, and then, processes illustrated in FIG. 19E and FIGS. 20A to 20C are performed.

In the process illustrated in FIG. 19A, a plurality of holes are formed in the surface 11a of the semiconductor substrate 11i (see FIG. 5D) by using a dry etching method or the like, and the formed holes are filled up with a conductive material through a plating process or the like, whereby vias 618, 13, and 14 are formed. At this time, each of the vias 618, 13, and 14 may extend from the surface 11a up to a position that is shallower than the rear surface 11ib. Then, a multi-layer wiring structure including multi-layer wirings 612 that are respectively connected to the vias 618, 13, and 14 is formed on the surface 11a of the semiconductor substrate 11i.

Then, the semiconductor substrate 11i is thinned by polishing the rear surface 11ib of the semiconductor substrate 11i until the vias 618, 13, and 14 are exposed. In this way, a thinned semiconductor substrate 11j is acquired. The vias 618, 13, and 14 pass through the thinned semiconductor substrate 11j from the surface 11a thereof to the rear surface 11b.

In the process illustrated in FIG. 19B, bumps of conductors of solder or the like are connected to regions in which the logic chip 20 is to be mounted, whereby connection end portions 23j and 24j are formed. Each connection end portion 23j is formed at a position corresponding to the power supply terminal 23i in the region in which the logic chip 20 is to be mounted. Each connection end portion 24j is formed at a position corresponding to the signal terminal 24i in the region in which the logic chip 20 is to be mounted.

In the process illustrated in FIG. 19C, the bumps of conductors of solder or the like are connected to the vias 13 and 14 exposed on the rear surface 11b of the semiconductor substrate 11j, whereby a connection end portion 33j and a connection end portion 34j are formed. Then, the semiconductor substrate 11j is divided into individual semiconductor chips, whereby a plurality of interposers 610 are acquired.

In the process illustrated in FIG. 19D, metal pillars 660 are connected to the vias 618 exposed on the rear surface 11b of the substrate 11 of the interposer 610.

In the process illustrated in FIG. 19E, the memory chip 30 is mounted on the second principal surface 10b of the interposer 610. At this time, by matching the positions of the interposer 610 and the memory chip 30, the power supply terminals 33i are connected to the connection end portions 33j so as to form power supply terminals 33, and the signal terminals 34i are connected to the connection end portions 34j so as to form signal terminals 34.

In the process illustrated in FIG. 20A, the memory chip 30 is mounted on the second principal surface 10b of the interposer 610, and the structure body to which the metal pillars 660 are connected are mounted on the package substrate 1. For example, the electrode portions 661 of the metal pillars 660 are connected to the power supply wiring 51 of the package substrate 1 (see FIG. 18).

In the process illustrated in FIG. 20B, the logic chip 20 is mounted on the first principal surface 10a of the interposer 610. For example, the logic chip 20 acquired in the process illustrated in FIG. 5C is arranged on the interposer 610 such that the power supply terminals 23i and the signal terminals 24i are disposed on the lower side. At this time, by matching the positions of the logic chip 20 and the interposer 610, a power supply terminal 23 is formed by connecting the power supply terminal 23i to the connection end portion 23j, and a signal terminal 24 is formed by connecting the signal terminal 24i to the connection end portion 24j (see FIGS. 5C and 20A).

In the process illustrated in FIG. 20C, a gap between the logic chip 20 and the interposer 610 is filled up with the sealing resin 4 so as to be sealed. In addition, gaps between the interposer 610, the memory chip 30, and the package substrate 1 are filled up with the sealing resin 603 so as to be sealed.

As described above, in the semiconductor device 600 according to the sixth embodiment, the metal pillars 660 are connected to the vias 618. The multi-layer wiring 612 of the interposer 610 electrically connects the vias 618 and the power supply terminal 23 of the logic chip 20. Accordingly, the combined resistance of a transmission path from the metal wire 40 to the power supply terminal 23 of the logic chip 20 can be configured to be low in an easy manner, and thus, a voltage drop at the time of transmitting power can be suppressed.

In addition, in the semiconductor device 600 according to the sixth embodiment, the interposer 610 is connected to the package substrate 1 through the metal pillar 660 using a flip chip connection. Accordingly, the resistance of the transmission path from the power supply wiring 51 of the package substrate 1 to the via 618 can be easily configured to be low, and thus, a voltage drop at the time of transmitting power can be further suppressed.

Furthermore, in the semiconductor device 600 according to the sixth embodiment, the interposer 610 is connected to the package substrate 1 through the metal pillar 660 using a flip chip connection. The height of the metal pillar 660 is larger than the thickness of the memory chip 30. Accordingly, the memory chip 30 can be separated from the package substrate 1, and thus, the heat radiation from the memory chip 30 can be improved in an easy manner.

In addition, in the method of manufacturing the semiconductor device 600 according to the sixth embodiment, the process of acquiring the logic chips 20 by dividing the semiconductor substrate into individual semiconductor chips, the process of acquiring the interposers 610 by dividing the semiconductor substrate into individual semiconductor chips, and the process of acquiring the memory chips 30 by dividing the semiconductor substrate into individual semiconductor chips can be performed in a parallel manner. Accordingly, a time required for manufacturing the semiconductor device 600 can be shortened in an easy manner.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
an interposer;
a logic chip mounted on a first principal surface of the interposer;
a memory chip mounted on a second principal surface of the interposer, the second principal surface is a principal surface arranged on an opposite side of the first principal surface; and
a package substrate on which the logic chip, the interposer, and the memory chip are mounted,
the interposer including:
a substrate;
a first via configured to electrically connect a signal terminal of the logic chip and a signal terminal of the memory chip to each other through the substrate;
a multi-layer wiring disposed on the first principal surface side of the substrate, a power supply terminal of the logic chip being electrically connected to the multi-layer wiring; and
a power supply pad disposed on the first principal surface side of the substrate and configured to be electrically connected to the power supply terminal of the logic chip through the multi-layer wiring, a metal wire being connected to the power supply pad,
the package substrate including a power supply wiring, and
the power supply pad and the power supply wiring being electrically connected to each other through the metal wire.

2. The semiconductor device according to claim 1, wherein
a plane dimension of the interposer is larger than a plane dimension of the memory chip.

3. The semiconductor device according to claim 1, wherein
a plane dimension of the interposer is a same as a plane dimension of the memory chip.

4. The semiconductor device according to claim 1, wherein
a plane dimension of the interposer is smaller than a plane dimension of the memory chip.

5. The semiconductor device according to claim 1, wherein
the multi-layer wiring includes a plane wiring pattern configured to be electrically connected between the power supply terminal of the logic chip and the metal wire.

6. The semiconductor device according to claim 1, wherein,
in a cross-sectional view, the multi-layer wiring includes wirings of a plurality of layers that are connected in a parallel manner in a stacking direction between the power supply terminal of the logic chip and the metal wire.

7. The semiconductor device according to claim 1, further comprising a redistribution arranged between the interposer and the memory chip, the memory chip being mounted on the second principal surface of the interposer through the redistribution.

8. The semiconductor device according to claim 7, wherein
the redistribution and the multi-layer wiring make a connection parallel to each other between the power supply terminal of the logic chip and the metal wire in a staking direction in a cross-sectional view.

9. A semiconductor device comprising:
an interposer;
a logic chip mounted on a first principal surface of the interposer;
a memory chip mounted on a second principal surface of the interposer, the second principal surface is a principal surface arranged on an opposite side of the first principal surface; and
a package substrate on which the logic chip, the interposer, and the memory chip are mounted,
the interposer including:
a substrate;
a first via configured to electrically connect a signal terminal of the logic chip and a signal terminal of the memory chip to each other through the substrate;
a second via to which a power supply terminal of the logic chip is electrically connected through the substrate;
a multi-layer wiring, to which the second via is electrically connected, disposed on the second principal surface side of the substrate; and
a third via configured to be electrically connected to the power supply terminal of the logic chip through the substrate, the second via and the multi-layer wiring, a metal wire being connected to a portion on a side of the first principal surface in the third via,
the package substrate including a power supply wiring, and
the third via and the power supply wiring being electrically connected to each other through the metal wire.

10. The semiconductor device according to claim 9, wherein
a plane dimension of the interposer is the same as a plane dimension of the memory chip.

11. The semiconductor device according to claim 9, wherein
the multi-layer wiring includes a plane wiring pattern configured to be electrically connected between the power supply terminal of the logic chip and the metal wire.

12. The semiconductor device according to claim 9, wherein,
in a cross-sectional view, the multi-layer wiring includes wirings of a plurality of layers that are connected in a parallel manner in a stacking direction between the power supply terminal of the logic chip and the metal wire.

13. The semiconductor device according to claim 9, further comprising a redistribution arranged between the interposer and the memory chip, the memory chip being mounted on the second principal surface of the interposer through the redistribution.

14. The semiconductor device according to claim 13, wherein
the redistribution and the multi-layer wiring make a connection parallel to each other between the power supply terminal of the logic chip and the metal wire in a stacking direction in a cross-sectional view.

15. A semiconductor device comprising:
an interposer;
a logic chip mounted on a first principal surface of the interposer;
a memory chip mounted on a second principal surface of the interposer, the second principal surface is a principal surface arranged on an opposite side of the first principal surface; and
a package substrate on which the logic chip, the interposer, and the memory chip are mounted,
the interposer including:
a substrate;
a first via configured to electrically connect a signal terminal of the logic chip and a signal terminal of the memory chip to each other through the substrate;
a multi-layer wiring, to which a power supply terminal of the logic chip is electrically connected, disposed on the first principal surface side of the substrate; and
a fourth via configured to be electrically connected to the power supply terminal of the logic chip through the substrate and the multi-layer wiring, a metal pillar being connected to a portion on a side of the second principal surface in the fourth via,
the metal pillar extending in a direction that is approximately perpendicular to the second principal surface,
the package substrate including a power supply wiring, and
the fourth via and the power supply wiring being electrically connected to each other through the metal pillar.

16. The semiconductor device according to claim 15, wherein
a plane dimension of the interposer is larger than a plane dimension of the memory chip.

17. The semiconductor device according to claim 15, wherein
the multi-layer wiring includes a plane wiring pattern configured to be electrically connected between the power supply terminal of the logic chip and the metal pillar.

18. The semiconductor device according to claim 15, wherein,
in a cross-sectional view, the multi-layer wiring includes wirings of a plurality of layers that are connected in a parallel manner in a stacking direction between the power supply terminal of the logic chip and the metal pillar.

19. The semiconductor device according to claim 15, wherein
a height of the metal pillar on a direction perpendicular to the first principal surface is larger than a thickness of the memory chip on the direction perpendicular to the first principal surface.

20. The semiconductor device according to claim 19, further comprising:
a first sealing member configured to seal a gap between the logic chip and the interposer; and
a second sealing member configured to have thermal conductivity higher than that of the first sealing member and seal a gap between the interposer and the memory chip, and seal a gap between the memory chip and the package substrate.
